(19) United States
(12) Patent Application Publication
(10) Pub. No.: US 2015/0090862 A1
(43) Pub. Date: Apr. 2, 2015

(54) LENS AND MANUFACTURING METHOD FOR THE SAME

(71) Applicant: DENSO CORPORATION, Kariya-city (JP)

(72) Inventors: Takayuki MATSUI, Nagakute-city (JP); Hisayoshi FUJIKAWA, Nagakute-city (JP); Hideo IIZUKA, Nagakute-city (JP); Hiroyuki WADO, Toyota-city (JP); Shuichi YAMASHITA, Okazaki-city (JP)

(21) Appl. No.: 14/498,164

(22) Filed: Sep. 26, 2014

(30) Foreign Application Priority Data
Sep. 30, 2013 (JP) 2013-203754
Sep. 24, 2014 (JP) 2014-194352

(51) Int. Cl. G02B 3/00; B29D 11/00; H01L 27/146; G02B 1/00; G02B 13/14

(52) U.S. Cl. CPC G02B 3/0087; G02B 1/00; G02B 13/14; H01L 27/14625; B29D 11/00009
USPC 250/208.1; 359/652; 359/356; 29/592

(57) ABSTRACT

A lens reflecting a light of a predetermined wavelength, or transmitting and condensing or diverging the light is provided. The lens includes a substrate, and
a quasi-periodic structure layer. A plane of the quasi-periodic structure layer is divided into unit cells and is filled with the unit cells in a two-dimensional period. The unit cell has a first region and a second region. An occupancy rate is changed as a distance from a center of the substrate. A resonance mode is defined by a relationship between the occupancy rate and the period length. A lowest order resonance mode is defined by the resonance mode. The period length is set to a predetermined value within a predetermined range including an optimum value. Another lens is provided. A minimum occupancy rate is defined by a smallest occupancy rate. A variation range of the occupancy rate changes across the minimum occupancy rate.

### CROSS REFERENCE TO RELATED APPLICATION

This application is based on Japanese Patent Application No. 2013-203754 filed on Sep. 30, 2013, Japanese Patent Application No. 2014-194352 filed on Sep. 24, 2014, the disclosure of which are incorporated herein by reference.

### TECHNICAL FIELD

A present disclosure relates to a lens having a quasi-periodic structure and a manufacturing method for the lens, which has a feature with respect to a quasi-periodic structure.

### BACKGROUND

Patent literature 1: US 2013/0027776 A1

Non-patent literature 1: D. Fattal et al., “Flat dielectric grating reflectors with focusing abilities,” Nature Photonics 4, pp. 466-470. (2010).

Non-patent literature 2: D. Fattal et al., “A Silicon Lens for Integrated Free-Space Optics,” (Conference Paper) Integrated-Photonics Research, Silicon and Nanophotonics, Toronto Canada, Page ITuD2 (2010).

Patent literature 1 and non-patent literature 1 disclose lenses whose one-dimensional periodic structures are similar to each other. The lenses have a structure that a ridge made from a stripe-shaped Si and a space region are periodically arranged alternately on a substrate made from SiO₂. A width of the ridge gradually reduces toward an end part of the substrate from the center of the substrate. Hereinafter, a structure formed from unit cells that are periodically arranged will be referred to as a quasi-periodic structure in the present disclosure. A sub-structure in each of the unit cells changes according to a predetermined rule. The lenses disclosed in patent literature 1 and non-patent literature 1 change a phase of light transmitting the substrate according to a transmission position by a one-dimensional quasi-periodic structure, and the lenses disclosed in patent literature a and non-patent literature 1 condense light.

Non-patent literature 2 discloses a lens using the same principle as lenses disclosed in patent literature 1 and non-patent literature 1. The lens in non-patent literature 2 extends the one-dimensional quasi-periodic structure into a two-dimensional quasi-periodic structure. Ridges made from Si are arranged in a hexagonal lattice shape on a substrate of SiO₂ in the lens of non-patent literature 2. A rate of the ridges occupying the hexagonal lattice stepwisely changes from a substrate center to an edge.

A Fresnel lens is known as a lens whose thickness is made thin. In the Fresnel lens, a curved surface shape of a surface of the lens is remained, a thickness of the lens is reduced concentrically in plan view, and a thickness of the lens is reduced in a saw-tooth way in a cross section. According to this configuration, the Fresnel lens condenses light by refraction on the curved surface and the lens is made thin.

The applicants of the present invention have found the following with respect to a lens.

The lenses disclosed in patent literature 1 and non-patent literature 1 substantially condenses only one polarized light (referred to as a first polarized light) perpendicular to a stripe direction or parallel to the stripe direction. The other polarized light perpendicular to the first polarized light may not be condensed by the lenses disclosed in patent literature 1 and non-patent literature 1. In addition, a period of the ridge structure of the lenses disclosed in patent literature 1, non-patent literature 1, and non-patent literature 2 is about 300 nm, that is, relatively short. The manufacturing of the lens may be difficult, and a cost reduction may be difficult. In addition, the manufacturing of the Fresnel lens may be difficult, and the manufacturing cost may be difficult.

### SUMMARY

It is an object of the present disclosure to provide a thin and cheap lens and a manufacturing method for the lens.

According to one aspect of the present disclosure, a lens reflecting a light of a predetermined wavelength, or transmitting and condensing or diverging the light is provided. The lens includes a substrate and a quasi-periodic structure layer positioned to the substrate. A plane of the quasi-periodic structure layer is divided into unit cells and is filled with the unit cells in a two-dimensional period. Each of the unit cells in the quasi-periodic structure layer has a first region and a second region. A refractive index of the substrate is expressed by n1. A refractive index of the first region is expressed by n2. A refractive index of the second region is expressed by n3. A following relationship is satisfied: n2≧n1>n3 or n2>n1≧n3. A square root of a ratio of an area of the first region to an area of one of the unit cells is defined as an occupancy rate. The occupancy rate of each of the unit cells is changed as each of the unit cells has a distance from a center of the substrate, and a plan-view shape of the first region remains a similar figure. In a virtual arrangement, the plane of the quasi-periodic structure layer is filled with the unit cells that have the occupancy rate and a period length in the two-dimensional period, the occupancy rate and the period length being constant over the plane of the quasi-periodic structure layer. A resonance mode is defined by a relationship between the occupancy rate and the period length in a condition where the occupancy rate and the period length are changed and a transmissivity of the virtual arrangement is equal to zero. A lowest order resonance mode is defined as the resonance mode in a case where the occupancy rate is minimal. An optimum value is a smallest value of a resonance width of the lowest order resonance mode. The period length of the unit cells in an actual quasi-periodic structure layer is set to a predetermined value within a predetermined range including the optimum value. A variation range of the occupancy rate of each of the unit cells changes across the lowest order resonance mode.

According to another aspect of the present disclosure, a lens reflecting a light of a predetermined wavelength, or transmitting and condensing or diverging the light is provided. The lens includes a substrate, and a quasi-periodic structure layer positioned to the substrate. The predetermined wavelength is equal to or more than 2 μm. A plane of the quasi-periodic structure layer is divided into unit cells. The plane of the quasi-periodic structure layer is filled with the unit cells in a two-dimensional period. Each of the unit cells in the quasi-periodic structure layer has a first region and a second region. The first region is made from a same material as the substrate. A refractive index of the substrate is expressed by n1. A refractive index of the first region is expressed by n2. A refractive index of the second region is expressed by n3. A following relationship is satisfied: n1=n2>n3, and n1≧3. An occupancy rate is defined by a square root of a ratio of an area of the first region to an area of one of the unit cells. The occupancy rate of each of the unit cells is changed as each of the unit cells has a distance from a center of the substrate, and a plan-view shape of the first region remains a similar figure. In a virtual arrangement, the plane of the quasi-periodic structure layer is filled with the unit cells that have the occupancy rate and a period length in the two-dimensional period, the occupancy rate and the period length being constant over the plane of the quasi-periodic structure layer. A minimum occupancy rate is defined by a smallest occupancy rate when the occupancy rate is changed in a predetermined period length and a transmissivity in a virtual arrangement has a smallest value. A variation range of the occupancy rate of each unit cell in an actual quasi-periodic structure layer changes across the minimum occupancy rate.

According to another aspect of the present disclosure, manufacturing methods for the lenses are provided.

According to the lenses and the manufacturing methods of the present disclosure, it is possible to provide a thin and cheap lens and a manufacturing method for the lens.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a plan view of a lens in a first embodiment from above;

FIG. 2 is a cross sectional view taken along line II-II in FIG. 1;

FIG. 3 is a drawing illustrating a structure of a unit cell;

FIG. 4 is a graph illustrating a relationship between a period length, an occupancy rate, and a transmissivity in the unit cell;

FIG. 5 is a graph illustrating a relationship between the period length, the occupancy rate, and a transmission phase in the unit cell;

FIG. 6 is an enlarged view illustrating a region VI in FIG. 4;

FIG. 7 is an enlarged view illustrating a region VII in FIG. 5;

FIG. 8 is a graph illustrating a relationship between the occupancy rate and the transmissivity;

FIG. 9 is a graph illustrating a relationship between the occupancy rate and the transmission phase;

FIG. 10A is a drawing illustrating a first mode;

FIG. 10B is a drawing illustrating a second mode;

FIG. 10C is a drawing illustrating a third mode;

FIG. 10D is a drawing illustrating a fourth mode;

FIG. 11 is a drawing illustrating a complex plane view of complex amplitude;

FIG. 12 is a drawing illustrating light transmitting the lens;

FIG. 13 is a drawing illustrating a structure of the unit cell in the lens in a second embodiment;

FIG. 14A is a graph illustrating the transmissivity along TE;

FIG. 14B is a graph illustrating the transmission phase along TE;

FIG. 15A is a graph illustrating the transmissivity along TM;

FIG. 15B is a graph illustrating the transmission phase along TM;

FIG. 16 is a plan view of a lens in a third embodiment from above;

FIG. 17 is a cross sectional view of a lens in a fourth embodiment;

FIG. 18 is a cross sectional view of a lens in a modification;

FIG. 19 is a cross sectional view of a lens in another modification;

FIG. 20 is a cross sectional view of a lens in a fifth embodiment;

FIG. 21 is a cross sectional view of a lens in another modification;

FIG. 22 is a cross sectional view of a lens in another modification;

FIG. 23A is a drawing illustrating a graph of a transmission phase amount φ(x);

FIG. 23B is a drawing illustrating a variation of an occupancy rate r;

FIG. 24A is a drawing illustrating another structure of the unit cell in the present disclosure;

FIG. 24B is a drawing illustrating another structure of the unit cell in the present disclosure;

FIG. 24C is a drawing illustrating another structure of the unit cell in the present disclosure;

FIG. 25A is a drawing illustrating a structure of another unit cell in the present disclosure;

FIG. 25B is a drawing illustrating a structure of another unit cell in the present disclosure;

FIG. 26A is a drawing illustrating another structure of the unit cell in the present disclosure;

FIG. 26B is a drawing illustrating another structure of the unit cell in the present disclosure;

FIG. 27 is a cross sectional view of another lens in the present disclosure;

FIG. 28 is a cross sectional view of another lens in the present disclosure;

FIG. 29 is a plan view of a lens in a sixth embodiment from above;

FIG. 30 is a cross sectional view of a lens in the sixth embodiment;

FIG. 31 is a graph illustrating a relationship between a period length, an occupancy rate, and a transmissivity of a unit cell;

FIG. 32 is a graph illustrating a relationship between the period length, the occupancy rate, and a transmission phase of the unit cell;

FIG. 33 is a graph illustrating a relationship between the occupancy rate and the transmissivity of the unit cell;

FIG. 34 is a graph illustrating a relationship between the occupancy rate and the transmission phase of the unit cell;

FIG. 35 is a drawing illustrating a configuration of the unit cell in a first modification of the sixth embodiment;

FIG. 36 is a graph illustrating a relationship between the occupancy rate and the transmissivity of the unit cell in the first modification of the sixth embodiment;

FIG. 37 is a graph illustrating a relationship between the occupancy rate and the transmission phase of the unit cell in the first modification of the sixth embodiment;

FIG. 38 is a drawing illustrating a configuration of the unit cell in a second modification of the sixth embodiment;

FIG. 39 is a graph illustrating a relationship between the occupancy rate and the transmissivity of the unit cell in the second modification of the sixth embodiment;

FIG. 40 is a graph illustrating a relationship between the occupancy rate and the transmission phase of the unit cell in the second modification of the sixth embodiment;

FIG. 41 is a drawing illustrating a configuration of the unit cell of a lens in a seventh embodiment;

FIG. 42A is a drawing illustrating a production process of the lens in the seventh embodiment;

FIG. 42B is a drawing illustrating a production process of the lens in the seventh embodiment;

FIG. 42C is a drawing illustrating a production process of the lens in the seventh embodiment;

FIG. 43 is a graph illustrating a relationship between the occupancy rate and the transmissivity of the unit cell in the seven embodiment; and

FIG. 44 is a graph illustrating a relationship between the occupancy rate and the transmission phase of the lens in the seventh embodiment.

### DETAILED DESCRIPTION

Followingly, specific embodiments of the present disclosure will be explained. It should be noted that the present disclosure is not limited to the described embodiments.

### First Embodiment

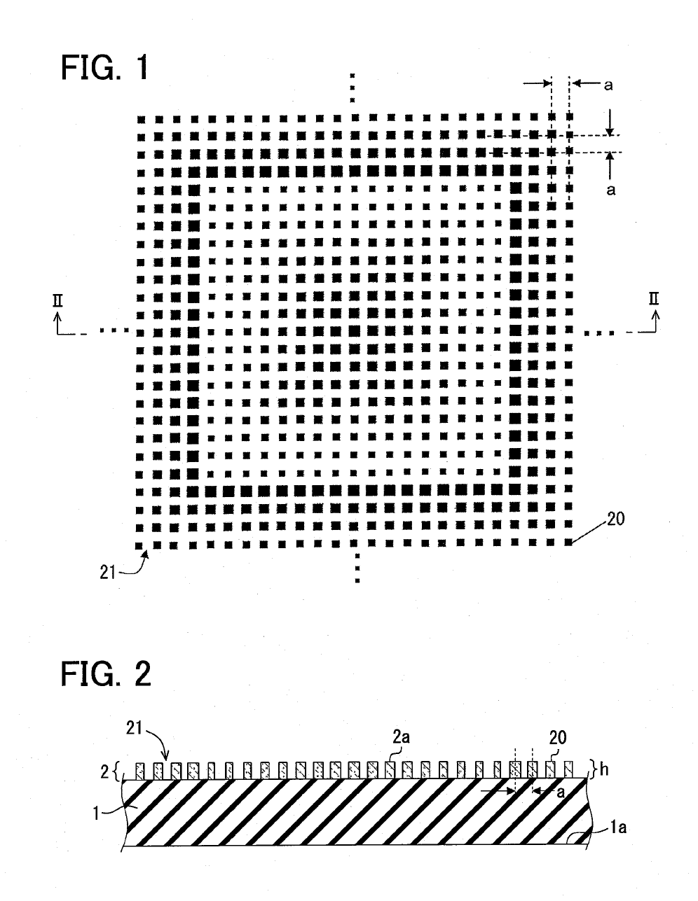

FIG. 1 is a plan view of a lens seen from above in a first embodiment, and FIG. 2 is the cross sectional view of the lens in FIG. 1. The lens of the first embodiment transmits and condenses light of a predetermined wavelength (e.g. 1.55 μm) irrespective of a polarization direction.

As described in FIG. 2, the lens in the first embodiment has a substrate 1 made from SiO₂ and a quasi-periodic structure layer 2 positioned on the substrate 1. Incidentally, a structure formed from unit cells that are periodically arranged will be referred to as a quasi-periodic structure in the present disclosure.

The substrate 1 has a thickness of 0.625 mm of SiO₂ (i.e. fused quartz), and is a square in plan view. A type of the substrate 1 may not be limited amorphous, but may be a crystal or polycrystal. In addition, a shape (also referred to as a plan-view shape) in plan view may not be limited to a square, but may be any arbitrary shape such as a circle, an ellipse, a rectangle, or the like. However, it may be preferable that the shape in plan view has a high symmetric property.

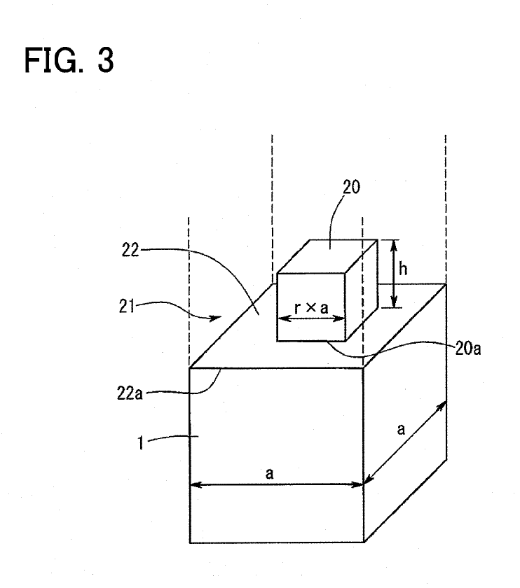

As described in FIG. 1 and FIG. 2, the quasi-periodic structure layer 2 has a structure having a ridge 20 made from Si and a space region filled with air between the ridges 20 in a square of a unit cell, when the quasi-periodic structure layer 2 is divided into square lattices in a plan view (with referring to FIG. 3). The unit cell 22 has a square shape, and each of the areas of the unit cells 22 is equal to each other. The ridge 20 corresponds to a first region in the present disclosure. The space region 21 corresponds to a second region in the present disclosure. The ridge 20 may be either a crystal state, a polycrystal state, or an amorphous state. A length of a side of the unit cell 22 is equal to 780 nm. The length of the one side of the unit cell 22 corresponds to a period length a of the unit cell 22.

In the present embodiment, it is supposed that a refractive index of the substrate 1 is defined as n1, a refractive index of the ridge is defined as n2, and a refractive index of the space region 21 is defined as n3. Here, n1 is equal to 1.45, n2 is equal to 3.45, and n3 is equal to about 1. Therefore, a following condition is satisfied: n2≧n1>n3. Incidentally, the refractive indexes are values of light having the wave length of 1.55 μm and being condensed by the lens in the first embodiment, and the refractive indexes correspond to a real number part of a complex refractive index.

A height h of the ridge 20, i.e., a thickness of the quasi-periodic structure layer 2, is equal to 1100 nm, and the height h of the ridge 20 is constant in every region. The shape of the ridge 20 is a rectangular parallelepiped, and has a square in plan view. The center of the ridge 20 and the center of the unit cell 22 are matched to each other, and each side 20a of the ridge 20 and each side 22a of the unit cell in the same side surface are parallel to each other.

The period length a (corresponding to the length of one side of the unit cell 22), the height h of the ridge 20, the refractive index n2 of the ridge 20, and a design wavelength λ (corresponding to a wavelength of light condensed by the lens in the first embodiment) may not be limited to the above values. However, it may be preferable that the values satisfy the following expression: a>λ²/(n2×h). In the lens in the first embodiment, λ is equal to 1500 nm, n2 is equal to 3.45, a is equal to 780 nm, and h is equal to 1100 nm, and therefore the above expression is satisfied. When each of the values is designed so as to satisfy the above expression, a structure of the quasi-periodic structure layer 2 may not be fine so much, and it may be possible to manufacture the lens in the first embodiment more easily.

When the length of the side 22a of the unit cell 22 is defined as a length a, the length of the side 20a of the ridge 20 is expressed by r×a. Here, r is equal to a square root of the rate of an area of the ridge 20 to an area of the unit cell 22. It is supposed that r is referred to as an occupancy rate. The occupancy rate r is a dimensionless quantity and takes the values from 0 to 1. Since the unit cell 22 and the ridge 20 have square shapes respectively, the occupancy rate r also represents a rate of the length of the side 20a of the ridge 20 to the length of the side 22a of the unit cell 22.

As described in FIG. 1 and FIG. 2, the occupancy rate r is changed from 0.3 to 0.6 as the unit cell 22 increases as a distance from the center part of the substrate 1 to an end part. The occupancy rate r gradually increases or decreases according to a position of the unit cell 22 as the unit cell 22 increases as a distance from the center part to the end part. The occupancy rate r gently decreases and rapidly increases. In other words, the occupancy rate r increases and decreases repeatedly in a saw-tooth shape. By increasing and decreasing in the saw-tooth shape, similar to the Fresnel lens, a focal distance may be shortened. In addition, a plane pattern of a variation of the occupancy rate r has a concentric square shape.

Although the plane pattern of the variation of the occupancy rate r has the concentric square shape coincided with the shape of the unit cell 22, the plane pattern of the variation of the occupancy rate r may have a concentric regular polygon shape, such as a concentric circle shape, a concentric regular hexagon shape, or the like, in addition to the concentric square shape. It may be preferable that the plane pattern of the variation of the occupancy rate r is a concentric circle shape from a viewpoint of a symmetric property especially. The occupancy rate r in the lens of the first embodiment increases or decreases in the saw-tooth shape as a distance from the center part of the substrate 1 to the end part. However, it may be unnecessary to increase or decrease in this way, and the occupancy rate r may decrease monotonously.

The period length a and the occupancy rate r are set so as to satisfy a following condition further.

The period length a is set to a predetermined range so that a resonance width of a lowest order resonance mode includes the narrowest value (i.e. an optimum value). The resonance mode is defined as follows. It is supposed to be an array that unit cells with a constant occupancy rate r and a constant period length a are filled in a two dimensional period on a plane as similar to an actual quasi-periodic structure layer 2 in a virtual arrangement. In this case, a transmissivity T of the virtual arrangement is expressed by a function f of r and a, and expressed by the following expression: T=f (r,a). The transmissivity T of the virtual arrangement is considered as the transmissivity of the unit cell 22 in the actual quasi-periodic structure layer 2. The resonance mode is defined by a curve satisfying a condition where the transmissivity T is equal to or less than 0.1, or defined by a belt shaped region satisfying a condition where the f (r, a)≦0.1. Usually, there are several resonance modes due to an influence of diffraction. Thus, in the multiple resonance modes, the curve or the belt shaped region having the smallest occupancy rate r is defined as the lowest order resonance mode.

In addition, a resonance width is defined as a half value width of a reduction peak of the transmissivity T. Incidentally, since the transmissivity T is a function of the occupancy rate r and the period length a, the resonance width may be defined by a half value width of a direction of the occupancy rate r, or may be defined by a half value width of a direction of the period length a.

The predetermined range including the optimum value may be determined arbitrarily as long as the lens has a desired property. However, it may be preferable that the predetermined range is in a range from 0.9 to 1.1 times of the optimum value. When the predetermined range is in the range from 0.9 to 1.1 times of the optimum value, the transmissivity of the lens may not decrease so much. More preferably, the predetermined range may be in a range from 0.95 to 1.05 times of the optimum value.

When the resonance width is expressed by the occupancy rate r, a step width that changes the occupancy rate r in the actual quasi-periodic structure layer 2 may be preferably set so that the number of change points of the occupancy rate r existing in the resonance width is 0.1 times or less of the number of all change points of the occupancy rate r in the quasi-periodic structure layer 2. In this case, there may be a few unit cells 22 whose transmissivity is equal to zero, and an influence on the transmissivity may be reduced as a whole of the lens. More preferably, the step width may be set so that the number of change points of the occupancy rate r is 0.01 times or less of the total number of all change points of the occupancy rate r.

In addition, when the resonance width is expressed by the occupancy rate r, the step width that changes the occupancy rate r in the actual quasi-periodic structure layer 2 may be set larger than the resonance width preferably. According to this configuration, the number of change points of the occupancy rate r existing in the resonance width is one at most, and therefore, the influence on the transmissivity may be more reduced as the whole of the lens.

The occupancy rate r is designed to change in a range across the lowest order resonance mode. That is, a variation range of the occupancy rate r includes a region of the lowest order resonance mode. It may be preferable that the variation range of the occupancy rate r includes only the lowest order resonance mode and does not include another resonance mode other than the lowest order resonance mode.

In addition, it may be preferable that the variation range of the occupancy rate r is set so that the resonance width of the lowest order resonance mode is overlapped with a range of 0.8 or more to 1.1 or less of a median of the variation range of the occupancy rate r. When the variation range of the occupancy rate r is set accordingly, it may be possible that a variation width (also referred to as a variation range) of a transmission phase is enlarged easily. In addition, it may be preferable that the variation range of the occupancy rate r is set so that the transmission phase is changed from −π to π.

The lens of the first embodiment is manufactured as follows. Initially, a layer including Si is formed on the substrate 1 by methods such as a vapor deposition, a chemical vapor deposition (CVD), a sputtering, or the like. A pattern mask similar to the space region 21 is provided on the layer made from Si by a photolithography, an electron-beam lithography, a nanoimprint, or the like. Next, a region that is not covered with the mask in the layer made from Si is etched until the substrate 1 is exposed. The above etching may be either a dry etching or a wet etching. Accordingly, the quasi-periodic structure layer 2 having the ridge 20 and the space region 21 with a pattern described in FIG. 1 and FIG. 2 is formed. The mask remained above the quasi-periodic structure layer 2 is removed. Accordingly, the lens of the first embodiment may be manufactured.

Incidentally, the quasi-periodic structure layer 2 may be formed on the substrate 1 by forming the ridge 20 made from Si, the ridge having the above pattern by a selective growth method or a lift-off method.

Since it is possible to manufacture the lens of the first embodiment by utilizing a manufacturing process of a Si semiconductor, it is possible to manufacture the lens easily at a low cost.

An operation and a principle of the lens in the first embodiment will be explained.

The lens of the first embodiment transmits and condenses light that is incident from a main surface 2a of the quasi-periodic structure layer 2 or from a back surface 1a of the substrate 1. That is, the lens of the first embodiment operates as a bidirectional convex lens.

Since the lens of the first embodiment has the quasi-periodic structure layer 2 formed by the ridge 20 and the space region 21 as described in FIG. 1 and FIG. 2, a phase shift amount of light is changed according to a transmission position. That is, according to a transmission position, the occupancy rate r is changed, and therefore, the phase shift amount of light transmitting the unit cell 65 is changed. According to a difference in the phase shift amount, the light transmitting the lens is condensed.

The phase shift amount depends on the occupancy rate r and a length a (i.e. a period length) of one side of the unit cell 22. The phase shift amount of the light transmitting the quasi-periodic structure layer 2 is controlled by changing the occupancy rate r. A transmission phase amount φ(x) is defined as the transmission phase amount at a position x. In this case, it is considered that the transmissivity T in the virtual arrangement corresponds to the transmissivity of the unit cell 22. The origin is defined to the center of the substrate 1, and an x-axis is defined as a straight line through the origin and parallel to the one side of the unit cell 22.

The transmission phase amount φ(x) is designed to satisfy the following expression:

φ(x)=(2π/λ)×(f+φₘₐₓλ/2π−(f²+x²)^{1/2}).

Herein, λ is equal to a design wavelength (corresponding to a wavelength of light condensed by the lens) in the first embodiment, f is equal to a focal distance, and φₘₐₓ is equal to a value of a phase shift amount at the origin.

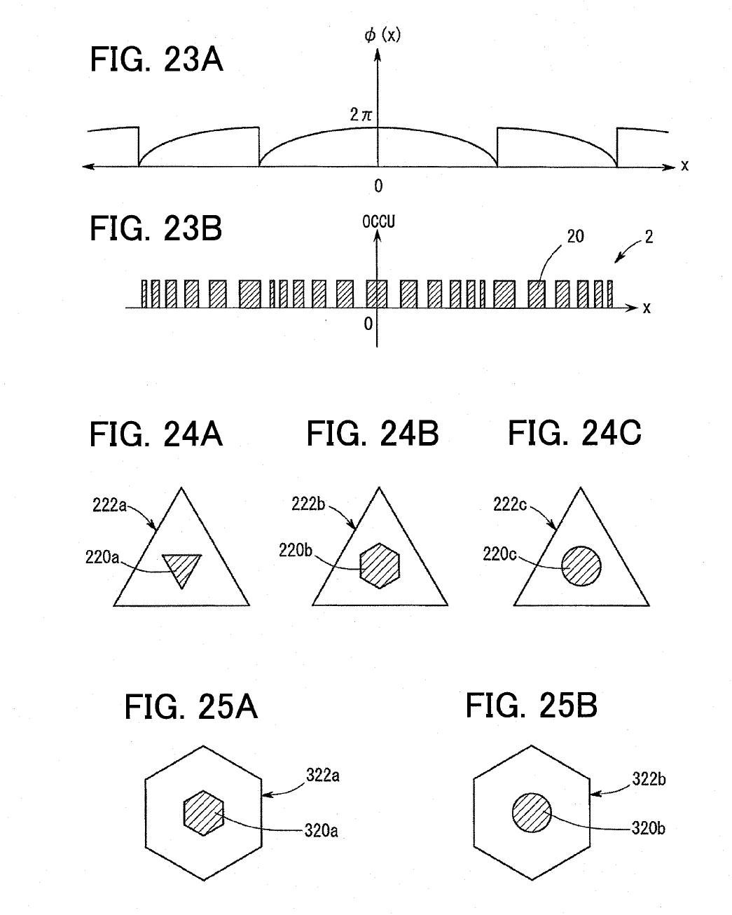

FIG. 23A is a graph of φ(x) when φₘₐₓ is set to 2π. Incidentally, φ(x) is folded in a range of from 0 to 2π. According to a position from the center of the lens, in order to satisfy the transmission phase amount given by the above expression, the occupancy rate r is changed as illustrated in FIG. 23B, and it may be possible that the light having the design wavelength is condensed.

In the lens in the first embodiment, the period length a is set to a value in the predetermined range including the optimum value that the resonance width of the lowest order resonance mode becomes the narrowest. The occupancy rate r changes across the lowest order resonance mode. Therefore, it is possible to easily change the transmission phase largely by changing the occupancy rate r, and the transmissivity is equal to or more than 90%. In addition, since the period length a is relatively large, the lens in the first embodiment may be produced easily. Incidentally, since the occupancy rate r is changed across the resonance mode, there may be the unit cell 22 whose transmissivity is equal to zero due to resonance in some cases. However, even when the transmissivity of the unit cell 22 is equal to zero, there may be several unit cells 22 at most. In the quasi-periodic structure layer 2 having many unit cells 22, a rate of the unit cell 22 whose transmissivity is equal to zero is very low, and the transmissivity of the lens as a whole may not be influenced.

Results of numerical simulations will be explained.

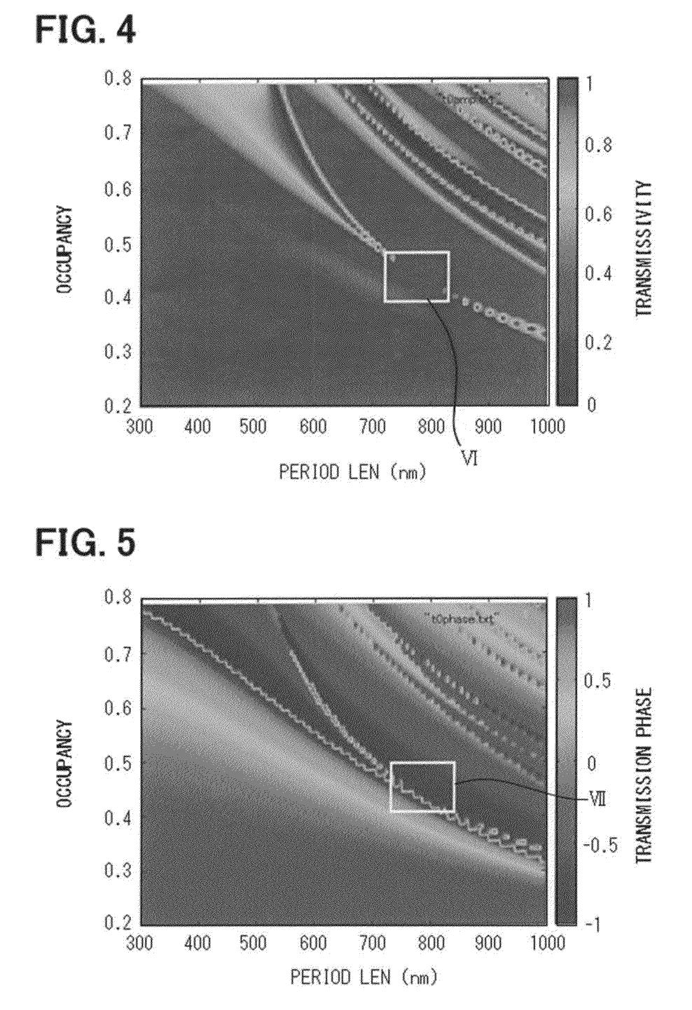

FIG. 4 and FIG. 5 are graphs illustrating the transmissivity and the transmission phase of the unit cell 22. In FIG. 4, a horizontal axis of the graph represents the period length a of the unit cell 22, a vertical axis represents the occupancy, and the gradation represents the transmissivity. The transmissivity is a value from 0 to 1. In FIG. 5, items in the horizontal axis and the vertical axis are identical with FIG. 4, and the gradation represents the transmission phase. The transmission phase is a value between −1 to 1 normalized by π. FIG. 4 and FIG. 5 are generated as follows. It is supposed that the height h of the ridge 20 is set to 1100 nm and the period length a and the occupancy rate r is constant. The unit cells 22 are filled (arranged) in a square lattice shape to take a virtual arrangement, and the transmissivity and the transmission phase of the virtual arrangement is numerically calculated by a rigorous coupled-wave analysis (RCWA) method. The calculated transmissivity and the calculated transmission rate are considered to be the transmissivity and the transmission rate of the unit cell 22 with the period length a and the occupancy rate r. In this numerical calculation, the variation width of the period length a is set to 5 nm, and the variation width of the occupancy rate r is set to 0.01.

In the graph in FIG. 4, the resonance modes are represented by multiple concentric curve lines. Incidentally, FIG. 4 illustrates a part of the multiple concentric curve lines. In addition, the transmission phase has a gap in level near the resonance mode as described in FIG. 5. Multiple resonance modes occur due to a diffraction effect generated by an array of the ridge 20, which is periodic. A resonance mode having the lowest occupancy rate r among the multiple resonance modes corresponds to the lowest order resonance mode.

In a region VI illustrated by a square around the period length 700 to 800 nm and around the occupancy rate of 0.4 in FIG. 4, it seems that the lowest order resonance mode disappears. Since a width of the lowest order resonance mode is narrower than the variation width of 0.01 of the occupancy rate in the simulation, the resonance is not captured in the variation width of calculation parameters used in FIG. 4 and FIG. 5.

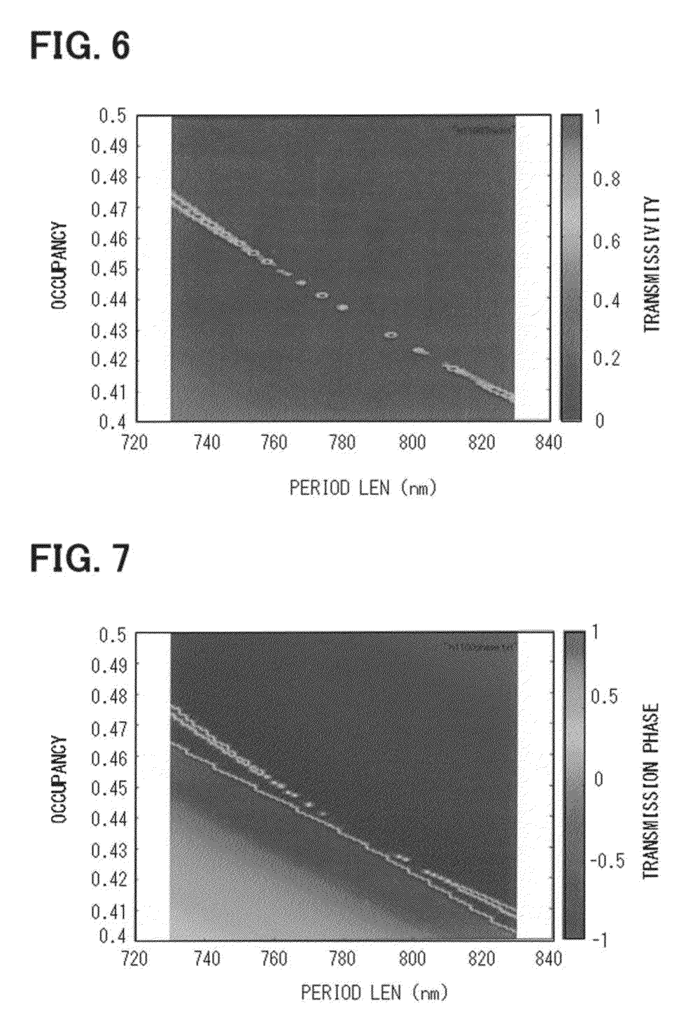

Thus, the region VI is calculated more fine by setting the period length a into 2 nm and the occupancy rate into 0.001 with respect to the variation width of the parameters. FIG. 6 and FIG. 7 are results of calculation. FIG. 6 describes the transmissivity, and the FIG. 7 describes the transmission phase. As described in FIG. 6, the resonance is not captured near the period length of 780 nm. That is, the resonance width is less than 2 nm of the period length, or is less than 0.001 of the occupancy rate.

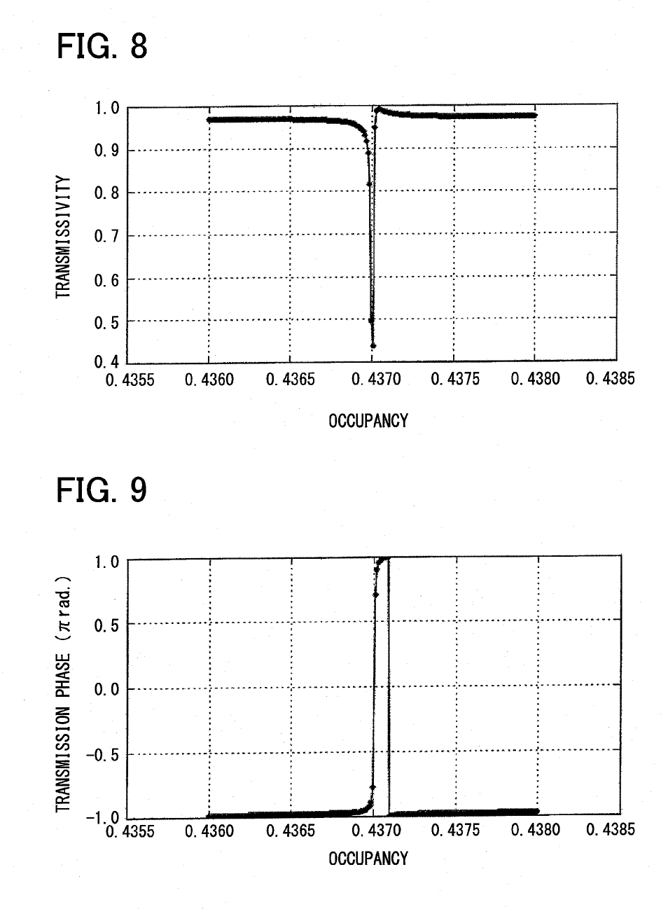

Therefore, the period length in set into 780 nm, the variation width of the occupancy is set to 0.00001, and the simulation is performed again. FIG. 8 and FIG. 9 are results of the calculation. In FIG. 8 the horizontal axis represents the occupancy rate, and the vertical axis represents the transmissivity. In FIG. 9, the horizontal axis represents the occupancy rate, and the vertical axis represents the transmission phase. As described in FIG. 8, there is an extremely narrow peak where the transmissivity increases or decreases sharply. In this case, the half value width of the peak is equal to 0.000025 by converting into the occupancy rate. From the calculation results, the resonance occurs in an extremely narrow range at the period length of 780 nm. Incidentally, although the peak of the transmissivity is not equal to 0 in FIG. 8, the peak of the transmissivity may be equal to 0 when the variation width of the occupancy rate r may be narrow enough.

As described above, in the lowest order resonance mode, there is a region where the resonance width is narrow, the region being captured only when the variation width of the parameters become extremely small. The lens in the first embodiment utilizes this region. In a case where the transmission phase is largely changed from −π to π by changing the occupancy rate, a region having a short period length should be used for improving the transmissivity of the lens without including the resonance mode. For example, a region of 300 to 400 nm of the period length may be used as described in FIG. 5. On the contrary, the lens in the first embodiment uses the region of 760 to 810 nm of the period length where the resonance width of the lowest order resonance mode is extremely narrow. The period length used in the lens of the first embodiment is about twice as compared with the period length of 300 to 400 nm, and therefore it may be possible that the quasi-periodic structure layer 2 is produced more easily. In the lens of the first embodiment, the resonance width is extremely narrow when the occupancy rate is changed across the lowest order resonance mode in the region of 760 to 810 nm of the period length, in order to change the transmission phase from −π to π. Since the resonance width is extremely narrow, no unit cell 22 may be resonant or several unit cells 22 may be resonant even if there are unit cells 22. The transmissivity may not be influenced as a whole of the lens. It is possible to provide a lens having a high transmittance.

The resonance is explained as the region where the transmissivity is equal to 0 at the time when the unit cell 22 is analyzed by the RCWA method using the period length and the occupancy rate as parameters. The resonance will also be explained by a mode coupling of the RCWA method. When an electromagnetic wave property of the unit cell 22 is expressed with a linear combination of multiple modes, two modes having the highest effective refractive index and the second highest effective refractive index are degenerated, and there are four modes including the degeneracy. The resonance will be explained as a case where the transmissivity is equal to 0 when the four modes are coupled.

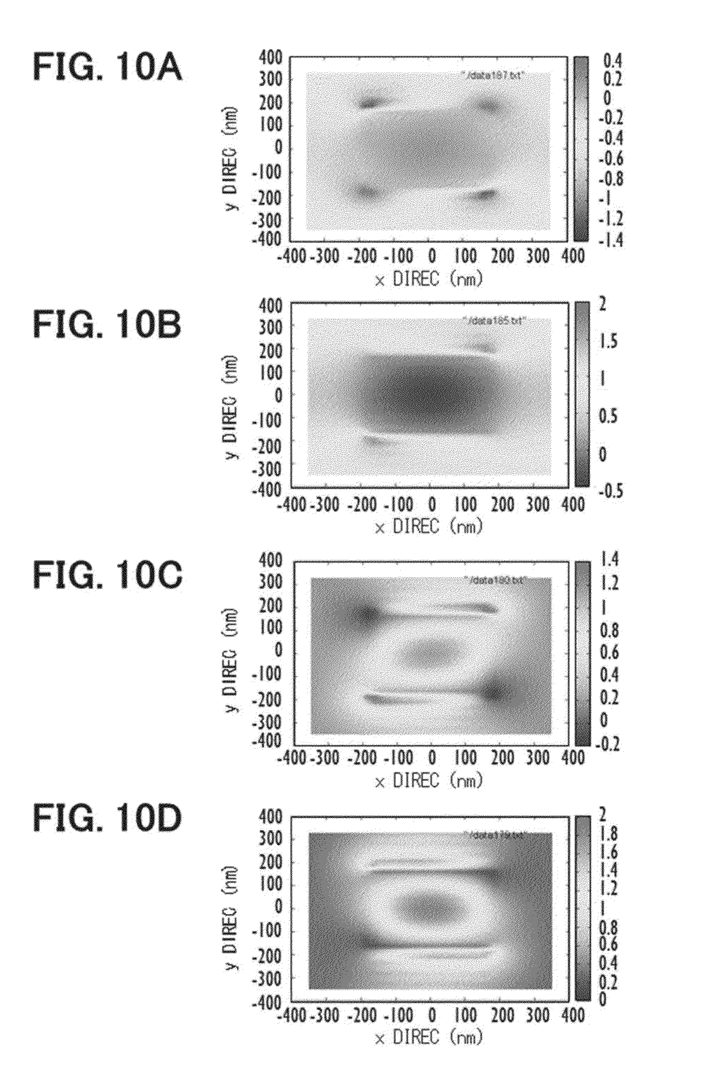

FIG. 10A to FIG. 10D illustrate four modes (a first mode to a fourth mode, respectively) having high effective refractive indexes including degeneracy and especially illustrates a field intensity in each of the modes. In graphs in FIG. 10A to FIG. 10D, a surface of the quasi-periodic structure layer 2 is defined as a xy plane, a direction parallel with one side of the unit cell 22 is defined as an x-axis, and another direction parallel with another side of the unit cell 22, perpendicular to the one side, is defined as a y-axis. The center of the ridge 20 is defined as the origin. Each of the effective refractive indexes is degenerated doubly since waves propagating to a positive direction and a negative direction with respect to a direction perpendicular to the xy plane.

Incidentally, the effective refractive index in FIG. 10A is equal to 0.5847, the effective refractive index in FIG. 10B is equal to 0.5847, the effective refractive index in FIG. 10C is equal to 2.2381, and the effective refractive index in FIG. 10D is equal to 2.2381.

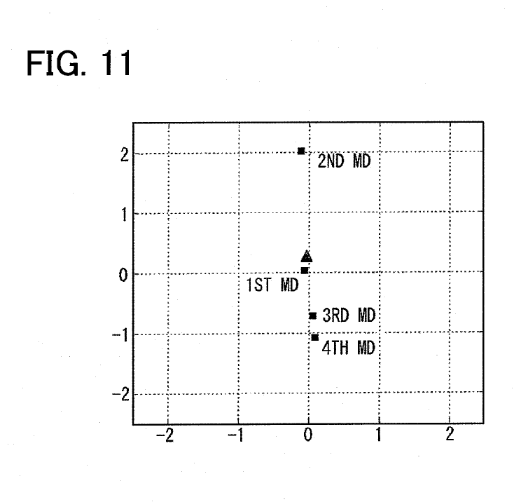

FIG. 11 is a drawing illustrating a complex plane of complex amplitude. In FIG. 11, four complex amplitudes of the four modes described in FIG. 10A to FIG. 10D and a synthetic amplitude of the four modes are plotted. A square symbols represent the four modes, and a triangular symbol represents the synthetic amplitude.

As described in FIG. 11, a position of the triangular symbol, which is the synthetic amplitude of the four modes, is almost equal to 0. Thus, the resonance is explained as a case where the four modes including the degeneracy are cancelled by coupling the four modes.

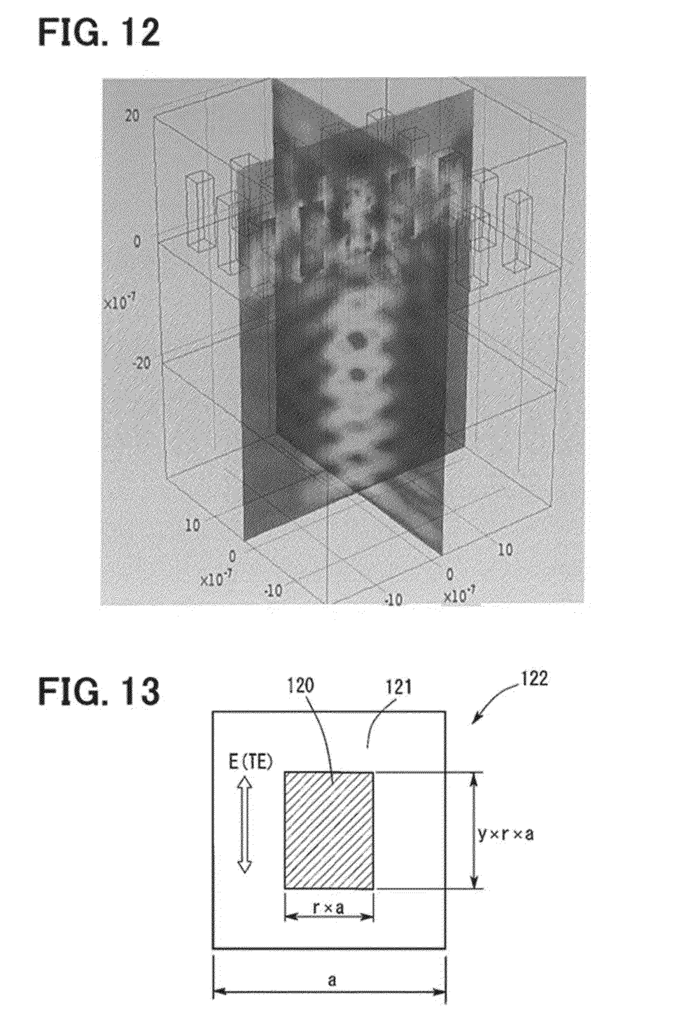

FIG. 12 is a simulation result of condensation of light of 1.55 μm of wavelength when the number of the unit cells 22 in the quasi-periodic structure layer 2 is equal to 5×5. In FIG. 12, light intensity is strong near the center of the array of the unit cells 22. The position that the light intensity is strong is expressed as a dot in FIG. 12. Light transmitting the quasi-periodic structure layer 2 is condensed as described in FIG. 12.

The lens in the first embodiment is thin, and since a manufacturing process of a Si semiconductor utilizes a manufacturing process of the lens, it is possible to manufacture the lens easily at a low cost.

### Second Embodiment

In a lens in the second embodiment, the unit cell 22 of the quasi-periodic structure layer 2 in the lens of the first embodiment is replaced to a unit cell 122 described in FIG. 13. Structure other than the unit cell 122 is similar with the lens in the first embodiment.

The unit cell 122 includes a rectangular ridge 120 at the center of the square region as described in FIG. 13. Length of the one side in the square region is equal to a. Each side of the ridge 120 is parallel with each side of the unit cell 122. A region other than the ridge 120 corresponds to a space region 121, which is filled with air. The side of the ridge 120 has a shorter side and a longer side since the ridge 120 is a rectangular shape. A length of the shorter side of the ridge 120 is expressed as r×a, and a length of the longer side is expressed as y×r×a. The symbol r is equal to a ratio of the length of the shorter side to the length of the side of the unit cell 122, and is equal to the occupancy rate. In addition, the symbol y represents magnification of the length of the longer side to the shorter side. The height of the ridge 120 is equal to 1100 nm as similar with the ridge 20 in the first embodiment.

Incidentally, the definition of the occupancy rate r is different from the first embodiment. However, the occupancy rate in the second embodiment corresponds to a constant multiple of the occupancy rate r in the first embodiment. Therefore, the result as similar with the following will be obtained even when the occupancy rate r is equal to a square root of the rate of the area of the ridge 120 to the area of the unit cell 122.

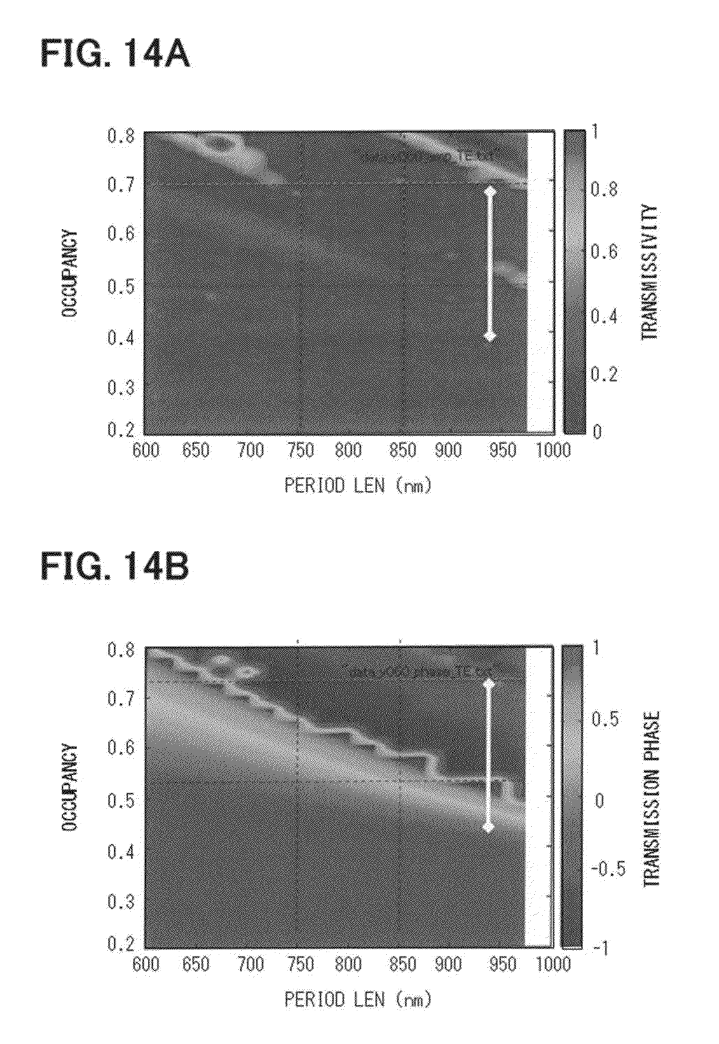

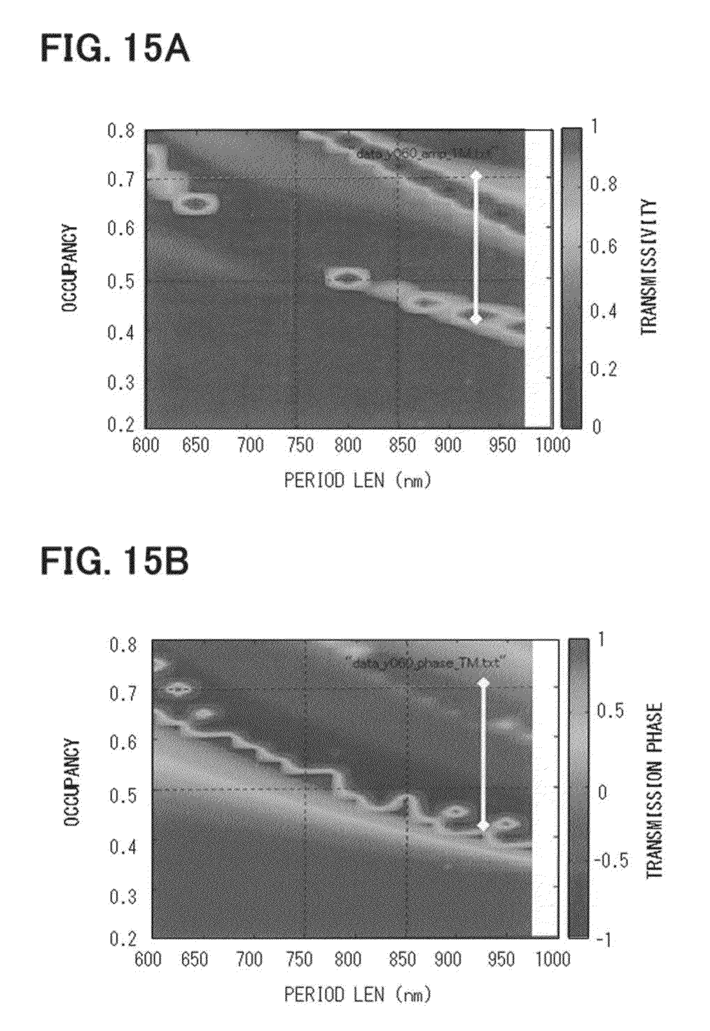

With respect to the unit cell 122, y is set to 0.6 and the period length a and the occupancy rate r are considered as parameters, and an analysis as similar with FIG. 4 and FIG. 5 is performed, so that the transmissivity and the transmission phase are calculated. It is supposed that a direction along the longer side of the ridge 120 is expressed as TE, and a direction along the shorter side is expressed as TM. FIG. 14A represents the transmissivity of TE, FIG. 14b represents the transmission phase of TE, FIG. 15A represents the transmissivity of TM, and FIG. 15B represents the transmission phase of TM.

As described in FIG. 14A, FIG. 14B, FIG. 15A, and FIG. 15B, a period length dependency and an occupancy rate dependency to the transmissivity are different between TE and TM. Similarly, the period length dependency and the occupancy rate dependency to the transmission phase are different between TE and TM.

From the result, a lens having a polarization property may be manufactured by altering a value of y, that is, by altering an aspect ratio of the ridge 120. For example, when the region (that is, 925 nm of the period length and the occupancy rate of near 0.4 to 0.7) near a segment connecting two diamond plots in FIG. 14 and FIG. 15 is used, it may be possible to manufacture the lens that condenses light along TE and does not so much condense light along TM.

Incidentally, in the second embodiment, a shape in plan view of the ridge is formed into a rectangular shape and the lens has the polarization property. However, when the unit cell 122 may be formed into a rectangular shape, the lens may have the polarization property.

### Third Embodiment

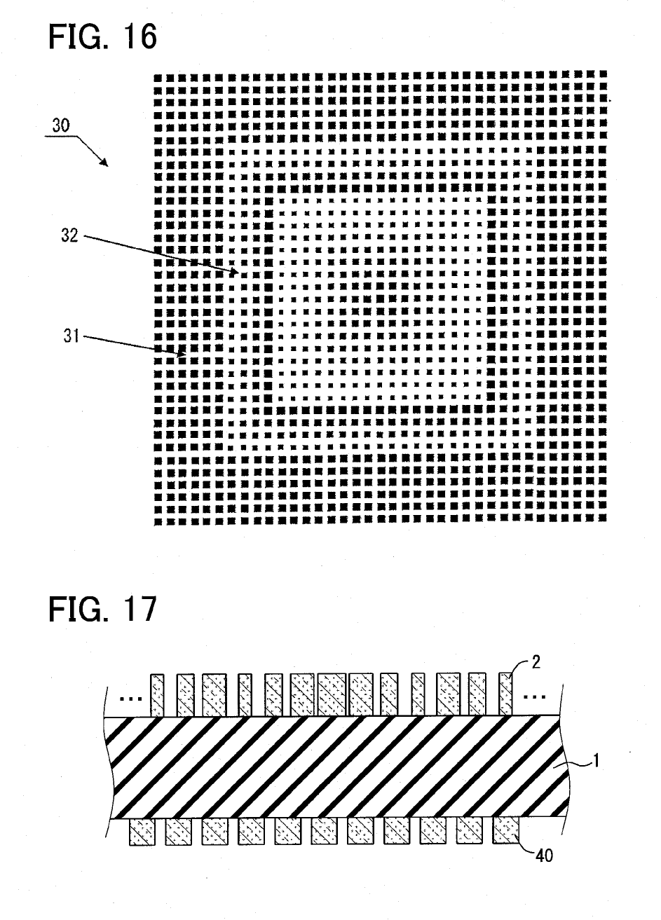

FIG. 16 is a plan view of the lens of the third embodiment seen from above. In the lens of the third embodiment, the quasi-periodic structure layer 2 in the first embodiment is replaced with a quasi-periodic structure layer 30 explained below, and the other configuration is similar with the lens in the first embodiment.

The quasi-periodic structure layer 30 in the third embodiment has a periodic structure 31 at a peripheral region of the quasi-periodic structure layer 2. The periodic structure 31, which is positioned to a peripheral region of the quasi-periodic structure layer 2, has the period length identical with the quasi-periodic structure layer 2 and the ridge 20 whose occupancy rate r is constant in the periodic structure. That is, the quasi-periodic structure layer 30 includes a structure (corresponding to an inner region 32) that the occupancy rate r of the ridge 20 is changed as similar with the quasi-periodic structure layer 2 in the first embodiment and another structure that the occupancy rate of the ridge 20 is constant (corresponding to the periodic structure 31). The periodic structure 31 surrounds the inner region 32 that condenses light as a lens.

The period length of the periodic structure 31 is equal to 780 nm, and the occupancy rate r is equal to 0.675. The periodic structure 31 reflects light of 1.55 μm, which is the design wavelength of the lens. Therefore, light of 1.55 μm of wavelength does not transmit the periodic structure 31, and only transmits the inner region 32, which is surrounded by the periodic structure 31 and functions as the lens. Thus, the periodic structure 31 functions as an aperture (or a diaphragm) of the lens.

Incidentally, the period length of the periodic structure 31 is identical with the period length of the inner region 32 in the third embodiment. It is not necessary to be the identical period length with the inner region 32. An arbitrary structure may be used as long as light of the design wavelength is reflected. However, from a viewpoint of a lens designing and a manufacturing easiness, the period length of the periodic structure 31 may be equal to the period length of the inner region 32, preferably.

### Fourth Embodiment

FIG. 17 is a cross sectional view of a lens of the fourth embodiment. The lens in the fourth embodiment further has a periodic structure layer 40 at a back surface of the substrate 1 of the lens in the first embodiment, and the other configuration is similar with the lens in the first embodiment.

The periodic structure layer 40 has ridges having identical shapes. The ridges in the periodic structure layer 40 are arranged in a two-dimensional period, and the space region between the ridges is filled with air. According to this periodic structure, the periodic structure layer 40 transmits light having a design wavelength, and reflects light having wavelength different from the design wavelength. When light is incident from a side of the quasi-periodic structure layer 2 to the lens in the fourth embodiment, the quasi-periodic structure layer 2 condenses light having the wavelength component of 1.55 μm, which is a design wavelength, and light transmits the substrate 1 and the periodic structure layer 40 to be radiated. On the contrary, light having a wavelength component other than 1.55 μm is reflected by the periodic structure layer 40 and does not transmit the periodic structure layer 40.

Therefore, according to the lens in the fourth embodiment, it is possible that light other than the design wavelength is prevented from transmitting.

Instead of the periodic structure layer 40, an absorption layer 41 may be provided as described in FIG. 18. The absorption layer 41 absorbs light of a specific wavelength. The absorption layer 41 may be made from material such as organic dye, metal oxide, or the like. According to this configuration, it is possible to obtain the effect similar to the effects when the periodic structure layer 40 is provided.

As described in FIG. 19, a low refractive layer 42 may be provided between the back surface of the substrate 1 and the periodic structure layer 40. Herein, the low refractive layer 42 is made from material having refractive index lower than a refractive index of the substrate. According to the low refractive layer 42, it is possible that wavelength other than the design wavelength is prevented from transmitting the periodic structure layer 40 more effectively. Alternatively, the absorption layer 41 may be provided between the back surface of the substrate 1 and the periodic structure layer 40.

### Fifth Embodiment

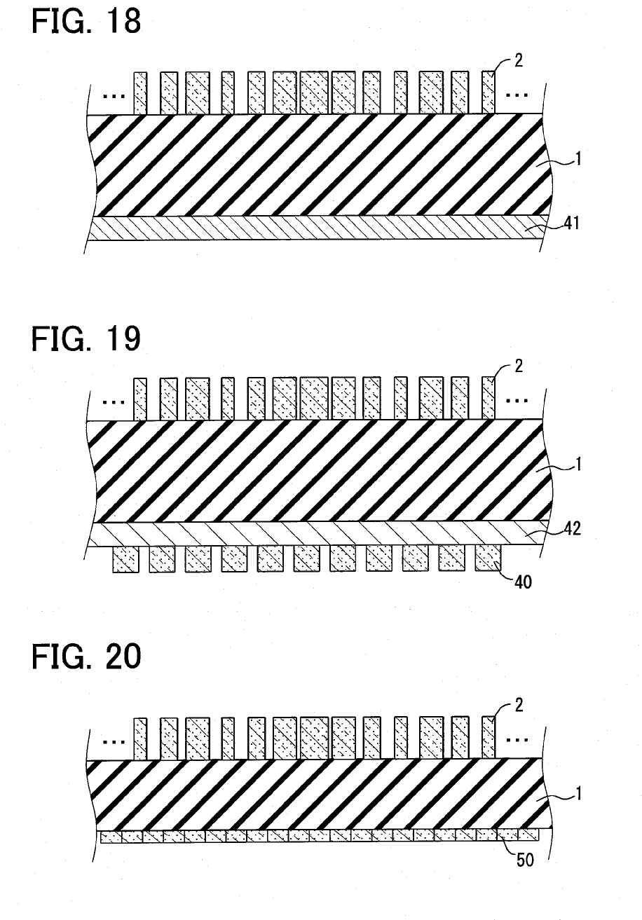

FIG. 20 is a cross sectional view of the lens in a fifth embodiment. The lens in the fifth embodiment has an imaging element array 50 at the back surface of the substrate 1 in the lens in the first embodiment (with referring to FIG. 20). The imaging element array 50 corresponds to a complementary MOS (CMOS), a charge coupled device (CCD), or the like. As described in FIG. 20, the lens in the fifth embodiment is integrally formed with the imaging element array 50 and the lens is integrated with the imaging element array 50. Therefore, the lens in the fifth embodiment may be effective for downsizing and thinning of a device.

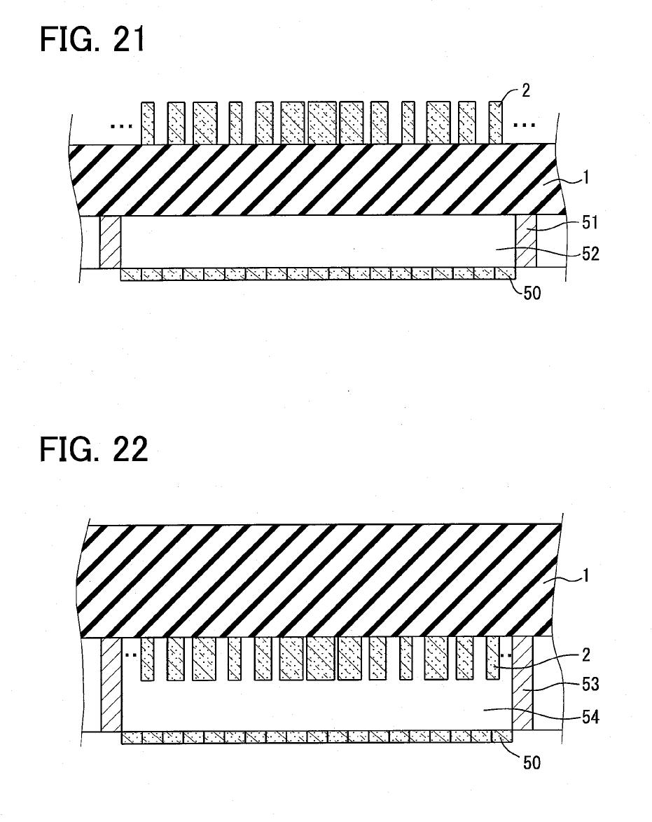

Incidentally, as described in FIG. 21, a spacer 51 may be provided between the back surface of the substrate 1 and the imaging element array 50, so that an air layer 52 may be provided between the back surface of the substrate 1 and the imaging element array 50. Alternatively, as described in FIG. 22, the imaging element array 50 may be provided above the quasi-periodic structure layer 2. In other words, the quasi-periodic structure layer 2 may be provided between the substrate 1 and the imaging element array 50. In FIG. 22, as similar to a configuration in FIG. 21, a spacer 53 is provided and an air layer 54 is provided between the quasi-periodic structure layer 2 and the imaging element array 50. However, the imaging element array 50 may be provided on the quasi-periodic structure layer 2 directly. Alternatively, instead of the air layers 52, 54, dielectric material may be used to fill a space.

### Sixth Embodiment

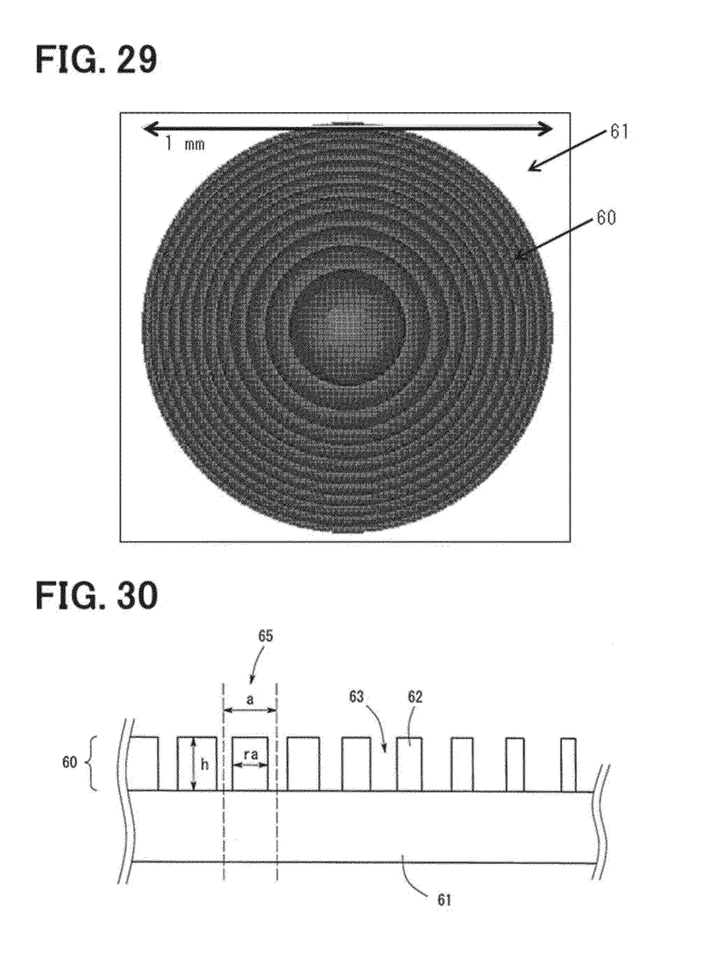

FIG. 29 is a plan view of a lens in a sixth embodiment seen from above, and FIG. 30 is the cross section view of the lens in FIG. 29. The lens of the sixth embodiment transmits and condenses light with a predetermined wavelength λ (e.g. 10 μm) irrespective of a polarization direction.

As shown in FIG. 29 and FIG. 30, the lens in the sixth embodiment is a lens provided with a quasi-periodic structure layer 60 above a surface of the substrate 61 made from Si.

The substrate 61 is made from Si of a single crystal, the thickness of the substrate 61 is a thickness of 625 μm, and a shape in plan view is a square. The substrates 61 may not be limited to a single crystal, and may be an amorphous state, and polycrystal. In addition, the shape in a plan view may not be limited to a square, but may be any arbitrary shape such as a circle, an ellipse, a rectangle, or the like. However, it may be preferable that the shape in plan view has a high symmetric property.

The quasi-periodic structure layer 60 is a structure formed in a predetermined pattern by etching to a predetermined depth on the surface of the substrate 61. As described in FIG. 29, the quasi-periodic structure layer 60 is formed in a circle region with a diameter of 1 mm on the substrate 61. In addition, as shown in FIG. 30, the quasi-periodic structure layer 60 includes a ridge 62 made from Si of a single crystal and a space region 63. That is, the region left behind without being etched corresponds to the ridge 62, and the etched region corresponds to the space region 63.

In addition, when the quasi-periodic structure layer 60 is divided into square lattice shapes in plan view, the quasi-periodic structure layer 60 has the ridge 62 and the space region 63 in the unit cell 65. A shape of the unit cell 65 is square, and areas of the unit cells 65 have equal to each other. The space region 63 is a region between the ridges 62, the space region 63 being filled with air. One side of the unit cell 65 is equal to 2.8 μm. The one side of the unit cell 65 corresponds to a periodic length a of the unit cell 65.

It is supposed that a refractive index of the substrate 61 is defined as n1, a refractive index of the ridge 62 is defined as n2, and a refractive index of the space region 63 is defined as n3. n1 and n2 are equal to 3.45, and n3 is about 1. Therefore, a following condition is satisfied: n1=n2>n3. Incidentally, the refractive index is a value in a wave length (e.g. 10 μm) of light condensed by the lens in the sixth embodiment. The refractive index corresponds to a real number part of a complex refractive index.

Incidentally, any kind of material other than Si may be used in the substrate 61 and the ridge 62 as long as a material has the refractive index of three or more and transmits the light of the predetermined wavelength λ. For example, the material of the substrate 61 and the ridge 62 may be Ge, SiGe, GaAs, GaN, or the like. In addition, the space region 63 may be filled up with a material having the refractive index n3, which satisfies n1=n2>n3. However, it may be preferable that a difference of the refractive indexes between the substrate 61 and the ridge 62, and the space region 63 is as large as possible, and it may be preferable that the difference of the refractive indexes is equal to or more than 1.

A height h of the ridge 62, i.e., a thickness of the quasi-periodic structure layer 60, is equal to 10 μm, and the height h of the ridge 62 is constant in every region. In addition, the shape of the ridge 62 is a rectangular parallelepiped in the same as the ridge 20 of the lens in the first embodiment in FIG. 3, and a square in plan view. A length of one side of the square is equal to ra. Herein, r corresponds to the occupancy rate defined in the first embodiment. The center of the ridge 62 and the center of the unit cell 65 are matched, and each side of the ridge 62 and each side of the unit cell 65 in the same side are parallel in plan view. Incidentally, the thickness of the quasi-periodic structure layer 60 is not limited to 10 μm, and a thickness of the quasi-periodic structure layer 60 may be determined appropriately as long as the lens in the sixth embodiment is easily produced and the transmissivity is not affected so much.

As described in FIG. 29, the occupancy rate r of each of the unit cell 65 decreases as a distance from the center of the substrate 61 to an end part of the substrate 61. Incidentally, it may be possible to shorten a focal distance, as similar to a Fresnel lens, by increasing and decreasing the occupancy rate r in a saw-tooth manner as a distance from the center of the substrate 61 to the end part. A plane pattern of a variation of the occupancy rate r is a pattern in which the occupancy rate r gradually decreases concentrically as shown in FIG. 29, and as a whole, the pattern of the quasi-periodic structure layer 60 is formed within a circle of 1 mm in diameter.

Furthermore, the occupancy rate r is designed to satisfy the following range.

Initially, it is supposed that, on a plane, the unit cell 65 having the occupancy rate r and the period length a, which are constant, are filled up in a two-dimensional period as similar to the actual quasi-periodic structure layer 60. That is, a virtual arrangement in which the unit cells 65 are filled up in the two-dimensional period is supposed. The transmissivity T in a predetermined period length a in the virtual arrangement corresponds to a function g of the occupancy rate r, and is expressed as T=g(r). Herein, it is considered that the transmissivity T is equal to the transmissivity of the unit cell 65 of the actual period length a and the actual occupancy rate r. The transmissivity T has a minimal value. A minimum occupancy rate r0 is defined as a value of r in a case where the transmissivity T has the minimal value. When multiple minimal values in the transmissivity T exist, the minimum occupancy rate r0 is defined as a value of r when the smallest occupancy rate r is obtained among the occupancy rates r having the minimal values. It is supposed that the occupancy rate r of the unit cell 65 in the actual quasi-periodic structure layer 60 changes in a range across the minimum occupancy rate r0. A meaning of “across the minimum occupancy rate r0” is that the minimum occupancy rate r0 is contained in a variation range of the occupancy rate r.

The lens of the sixth embodiment is produced as follows. Initially, a mask of the same pattern as the space region 63 is formed by a photolithography, an electron beam lithography, a nanoimprint, or the like on the substrate 60 made from Si. Next, a field, which is not covered with the mask, is etched to a predetermined depth. The etching may be either dry etching or wet etching. The quasi-periodic structure layer 61 having the pattern described in FIG. 29 and FIG. 30 is formed. Next, the mask remained on the quasi-periodic structure layer 61 is removed. The lens in the sixth embodiment is produced.

The lens of the sixth embodiment has the same operation principle as the lens of the first embodiment. That is, by being the quasi-periodic structure layer 60, the occupancy rate r of the unit cell 65 is different according to a transmission position of light, and accordingly, phase shift amounts of the light transmitting the unit cell 65 are different. According to a difference in the phase shift amount, the light transmitting the lens is condensed.

Incidentally, when the phase shift amount of the light transmitting the unit cell 65 is designed, it is considered that the transmissivity T in the virtual arrangement having the occupancy rate r corresponds to the transmissivity of the unit cell 65 having the period length a and the occupancy rate r.

Herein, in the lens of the sixth embodiment, the variation range of the occupancy rate r is set to a range across the occupancy rage r0, which is the occupancy rate r when the transmissivity T has the minimal value. Since the transmission phase amount of the unit cell 65 changes largely around the minimum occupancy rate r0, it is possible to change the transmission phase of the unit cell 65 a lot by setting the variation range across r0. It is possible to easily perform a design and a manufacturing of the lens in the sixth embodiment. It is possible to reduce a cost. Incidentally, it may be preferable that the variation range of the occupancy rate r corresponds to a range where the transmission phase of the unit cell 65 changes from −π to π. In addition, although the transmissivity of the lens in the sixth embodiment may reduce as compared with the lens in the first embodiment in some cases, the design and the manufacturing are simpler than the first embodiment.

Various simulation results about the lens in the sixth embodiment will be explained.

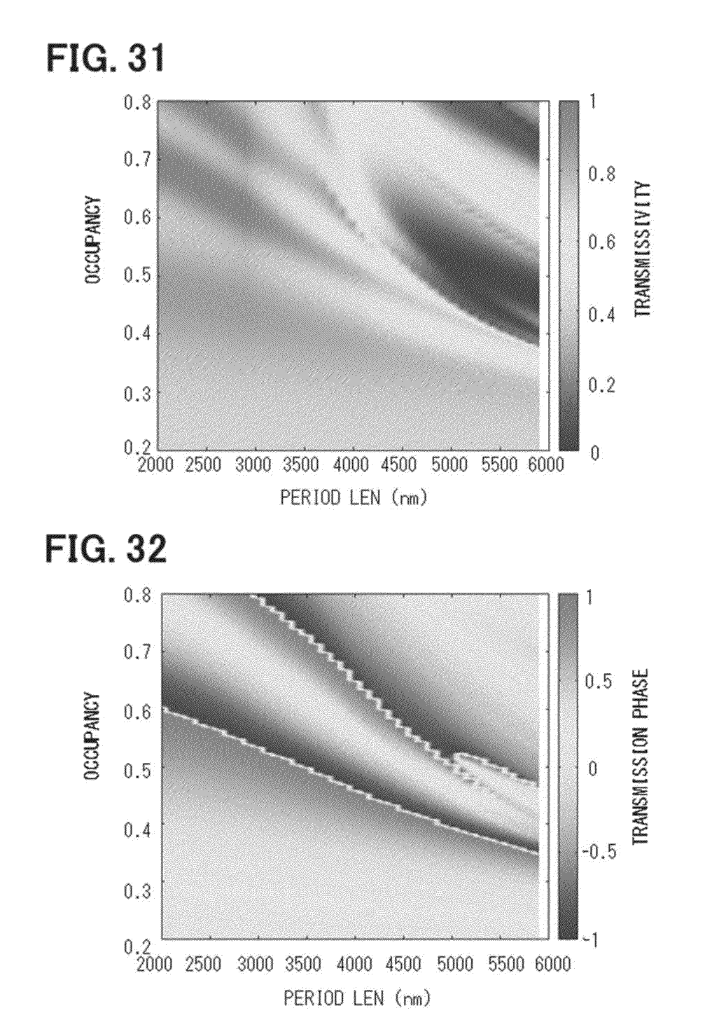

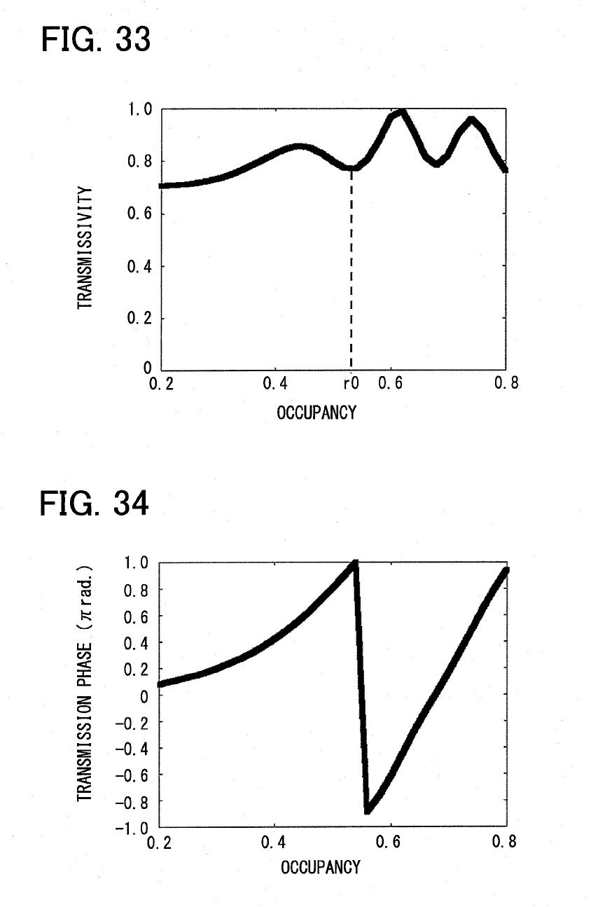

FIG. 31 is a graph illustrating a relationship between the period length a, the occupancy rate r, and the transmissivity r in the unit cell 65. FIG. 32 is a graph illustrating a relationship between the period length a, the occupancy rate r, and the transmission phase in the unit cell 65. The transmissivity and the transmission phase are calculated with the same technique as FIG. 4 and FIG. 5 in the first embodiment. However, a variation width of the parameters is set to 2000 nm to 6000 nm in the period length a and 0.2 to 0.8 in the occupancy rate. FIG. 33 is a graph illustrating a relationship between the occupancy rate r and the transmissivity when the period length a of the unit cell 65 is equal to 2.8 μm. FIG. 34 is a graph illustrating the transmission phase when the period length a of the unit cell 65 is equal to 2.8 μm.

As described in FIG. 32, a belt shaped region where the transmission phase changes largely exists. As described in FIG. 33, the transmissivity changes wave like shape when the occupancy rate r changes. In the range of 0.2 to 0.8 of the occupancy rate r, the transmissivity is equal to or more than 70%, and is equal to about 80% on average. There are two minimal values in the range of 0.2 to 0.8 of the occupancy rate r. The smallest occupancy rate r of the two occupancy rates r having the minimal values corresponds to the minimum occupancy rate r0. The minimum occupancy rate r0 is about 0.55 determined from FIG. 33. The transmission phase gradually increases as the occupancy rate r increases from 0.2, as described in FIG. 34. After the transmission phase reaches π around r0, the transmission phase steeply decreases to near −π, and then the transmission phase increases greatly again. Therefore, when the occupancy rate is changed across r0, it is possible that the phase shift amount of the light transmitting the unit cell 65 is changed largely. For example, it will be a transmission phase when changing occupancy rate r of unit cell 65 from 0.5 to 0.8. It can be made to change from −π to π.

Incidentally, the period length a is not limited to 2.8 μm as described in the sixth embodiment and the period length a may be set arbitrarily. It may be preferable that the period length a is equal to or less than 3/2 times of λ/n1. For example, 3/2 times of λ/n1 in the sixth embodiment is equal to 4.35 μm since λ is equal to 10 μm and n1 is equal to 3.45. When the transmissivity is more than 3/2 times of λ/n1, this case may not preferable since a region having a low transmissivity is included a lot when the occupancy rate r is changed as described in FIG. 31. In addition, it may be preferable that the period length a is ½ times of λ/n1 or more from a viewpoint of an ease of production. More preferably, the period length a may be ½ times of λ/n1 or more and 5/4 times of λ/n1 or less. More preferably, the period length a may be ¾ times of λ/n1 or more and λ/n1 or less.

### First Modification of Sixth Embodiment

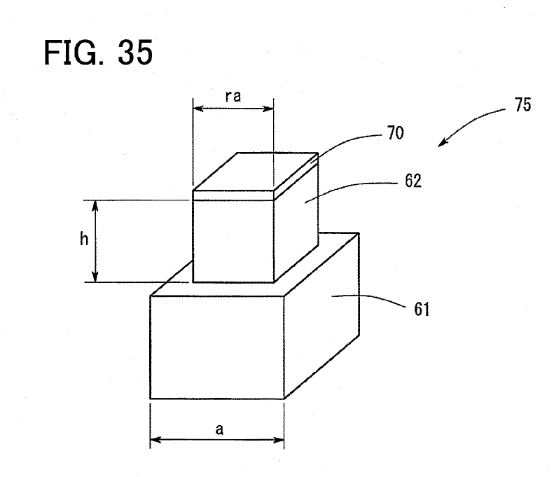

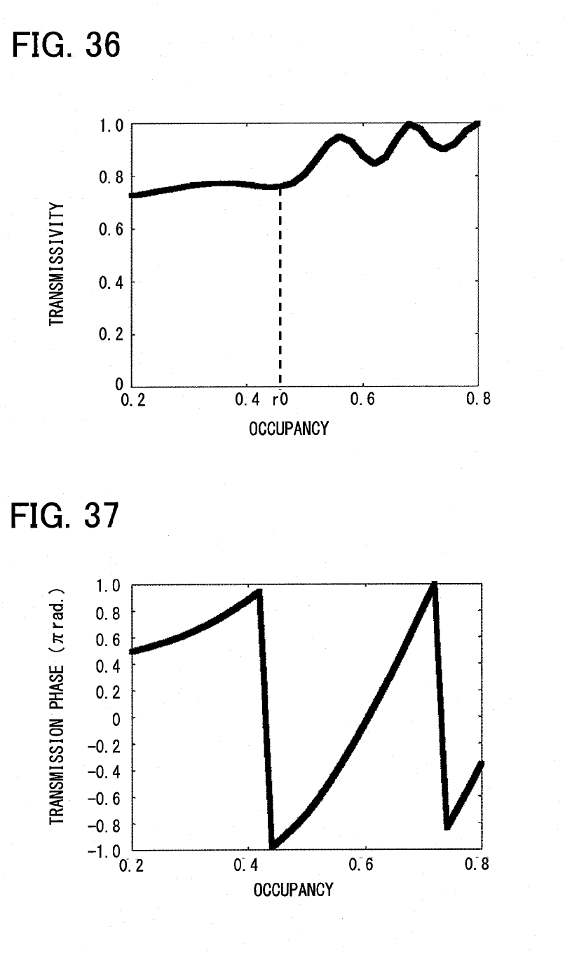

The first modification of the sixth embodiment transposes the unit cell 65 in the sixth embodiment to an unit cell 75 described in FIG. 35, and other configurations are the same as the sixth embodiment.

As described un FIG. 35, the unit cell 75 has a configuration that a low refractive layer 70 is provided on the ridge 62 of the unit cell 65 in the sixth embodiment. The low refractive layer 70 is made from BaF₂ (barium fluoride) of the refractive index of 1.4, and has a thickness of 2.4 μm.

A material of the low refractive layer 70 is not limited to barium fluoride, and any arbitrary material may be used as long as the material is transparent in the set wavelength A and the refractive index of the material is lower than the refractive index of the ridge 62. For example, the material may be a material such as CaF₂, MgF₂, LiF, SiO₂, ZnSe, KBr, KCl, Al₂O₃, NaCl, ZnS or the like, having a high transmissivity to an infrared light. Although the thickness of the low refractive layer 70 is set arbitrarily as long as an interference to the light of the set wavelength λ is not produced, it may be preferable that the thickness of the low refractive layer 70 is thin so as to reduce an absorption of the light by the low refractive layer 70 itself. For example, the thickness of the low refractive layer 70 may be equal to or less than a half of the height h of the ridge 62.

The light reflection in a case where the light is incident from a side of the low refractive layer 70 is reduced by providing the low refractive layer 70, and therefore, it is possible to improve the transmissivity of the unit cell 75.

FIG. 36 is a graph illustrating a relationship between the occupancy rate r and the transmissivity when the period length a of the unit cell 75 is set to 2.8 μm. FIG. 37 is a graph illustrating the transmission phase when the period length a of the unit cell 75 is equal to 2.8 μm. The transmissivity and the transmission phase are calculated as similar to a case in FIG. 33 and FIG. 34.

As shown in FIG. 36, the transmissivity is improved as compared with a case of FIG. 33 on the whole. As described in FIG. 36, r0 is about 0.47. As described in FIG. 37, when the occupancy rate r is changed across r0, it is possible to change the transmission phase of the unit cell 75 greatly.

### Second Modification of Sixth Embodiment

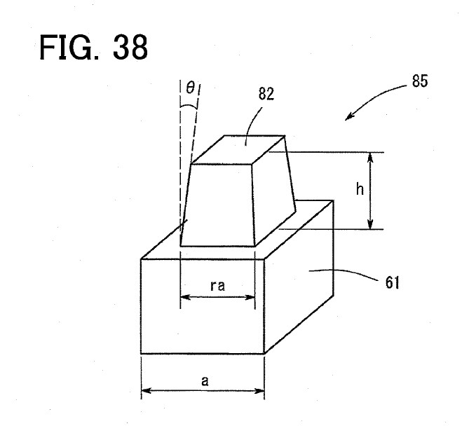

The second modification of the sixth embodiment transposes the unit cell 65 in the sixth embodiment to an unit cell 85 described in FIG. 38, and other configurations are the same as the sixth embodiment.

As described in FIG. 38, in the unit cell 85, the ridge 62 in the unit cell 65 is transposed to the ridge 82. The ridge 82 has a shape of a truncated square pyramid in which four side surfaces of a rectangular parallelepiped having a square in plan view are tilted three degrees from a direction vertical to the substrate 61. A tilt direction is a direction where a cross section area parallel to the substrate 61 of the ridge 82 decreases as a distance from the substrate 61. An under surface (corresponding to a surface touching with the substrate 61) of the ridge 82 is a square whose length of one side is equal to ra, similar to the ridge 62. That is, the occupancy rate r corresponds to a rate of the area of the ridge 82 on a surface touching with the substrate 61 to the area of the unit cell 75.

The tilt angle of the side surface of the ridge 82 is not limited to three degrees, and any tilt angle may be used as long as the tilt angle of the side surface is more than zero degree. However, when the tilt angle is too large, the ridge 82 becomes a pyramid and the height of the ridge 82 is smaller than h. Therefore, the tilt angle is set into a range where the ridge 82 is not smaller than h. For example, the tilt angle is equal to or less than 5 degrees. In addition, it is not necessary that the all four side surfaces are tilted, and at least one of the side surfaces may be tilted. Furthermore, any shape may be used as long as a cross section area parallel to the substrate 61 of the ridge 82 gradually reduces as a distance from the substrate 61.

When the ridge 82 has the above shape, a reflection of light at the side surface of the ridge 82 reduces and it is possible to improve the transmissivity of the unit cell 85.

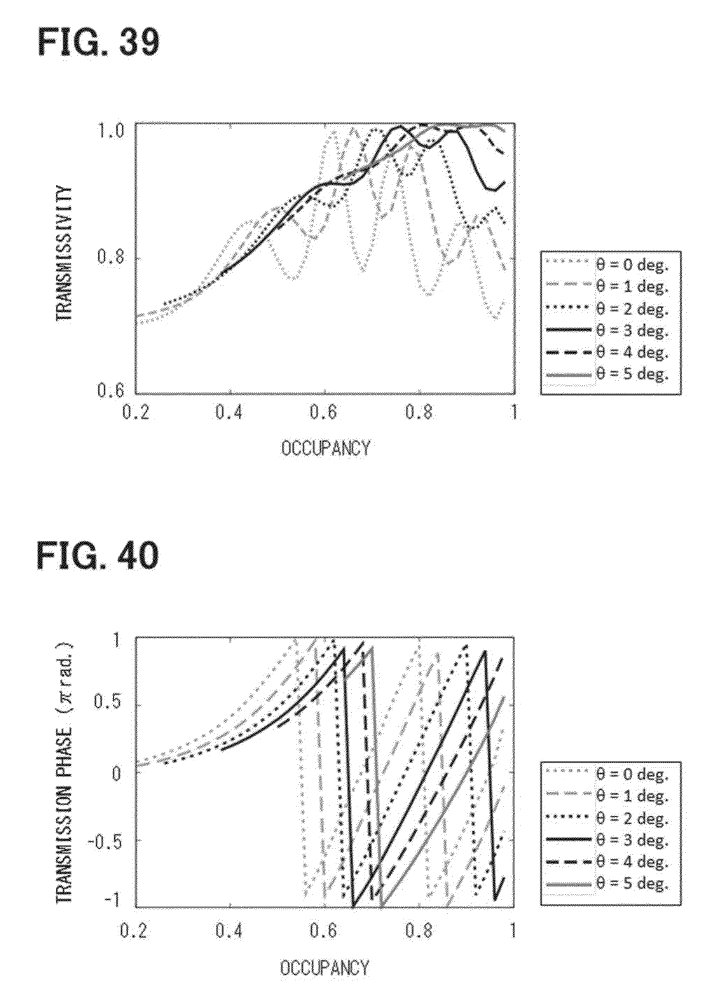

FIG. 39 is a graph illustrating a relationship between the occupancy rate r and the transmissivity when the period length a of the unit cell 85 is equal to 2.8 μm. FIG. 40 is a graph illustrating the transmission phase when the period length a of the unit cell 85 is equal to 2.8 μm. The transmissivity and the transmission phase are calculated as similar to a case in FIG. 33 and FIG. 34. The tilt angle of the side surface of the ridge 82 is changed by 1 degree unit from 0 degree to 5 degrees, and calculated the transmissivity and the transmission phase at each angle.

As shown in FIG. 39, when the tilt angle of the side surface of the ridge 82 is set to 1 to 5 degrees, the transmissivity is improved on the whole as compared with a case where the tilt angle is set to zero degree (that is, in the same as the ridge 62). In addition, the transmissivity tends to be improved as the tilt angle is large. It may be possible to largely change the transmission phase of the unit cell 85 by changing the occupancy rate r in every tilt angle, as shown in FIG. 40.

It is possible to control the tilt angle of the side surface of the ridge 82 by an etching condition when forming the ridge.

### Seventh Embodiment

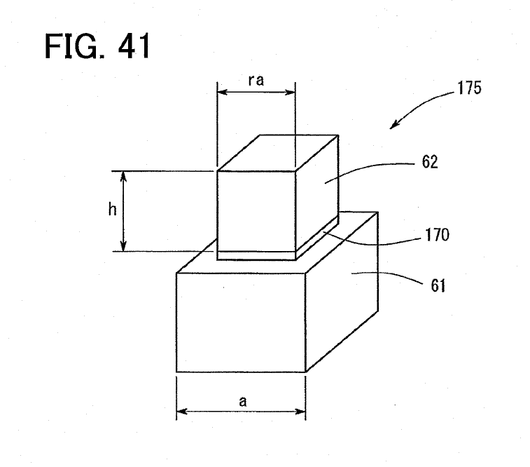

The lens in a seventh embodiment transposes the unit cell 65 in the sixth embodiment to an unit cell 175 described in FIG. 41, and other configurations are the same as the sixth embodiment.

As described in FIG. 41, the unit cell 175 in the lens of the seventh embodiment has an etching stopper layer 170 made from SiO₂, the etching stopper layer 170 being provided between the substrate 60 and the ridge 62. A configuration other than this structure is similar to the configuration of the unit cell 65.

The etching stopper layer 170 functions as an etching stopper when the ridge 62 is formed by etching. A material of the etching stopper layer 170 is not limited to SiO₂, and any material may be used as long as a material has an etching resistance property. It may be possible to easily produce the lens in the seventh embodiment with a 501 substrate by using SiO₂.

It may be preferable that the thickness of the etching stopper layer 170 is as possible as thin in a range capable of forming. For example, it may be preferable that the thickness of the etching stopper layer 170 is equal to or less than 1 μm. When the etching stopper layer 170 is made thin, it may be possible to reduce an absorption of light in the etching stopper layer 170. In addition, it may be possible to improve a strength of the ridge 62. In a manufacturing process of the lens of the seventh embodiment, it may be possible to reduce an side etching quantity by the etching stopper layer 170.

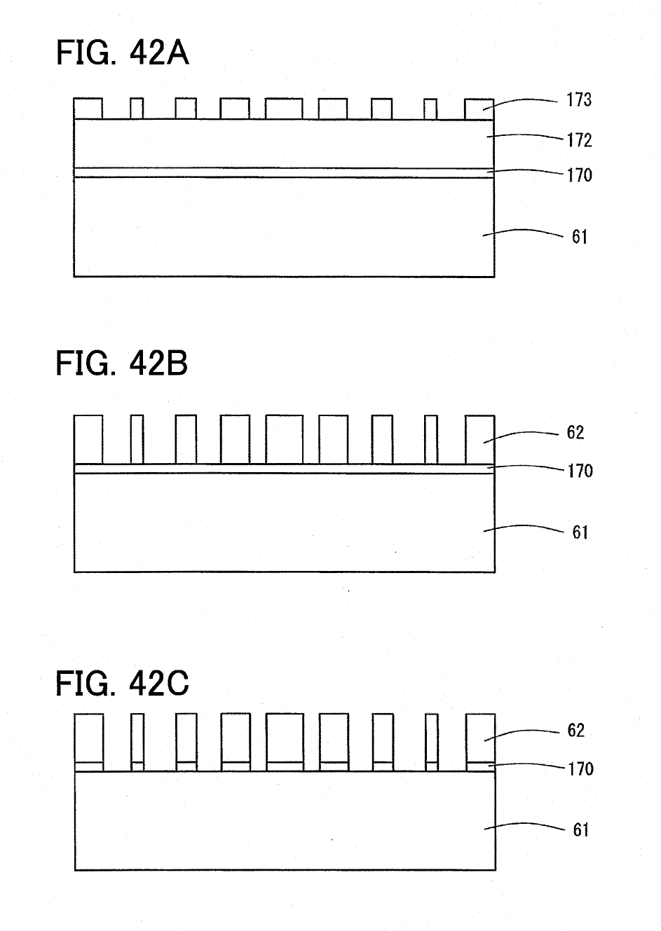

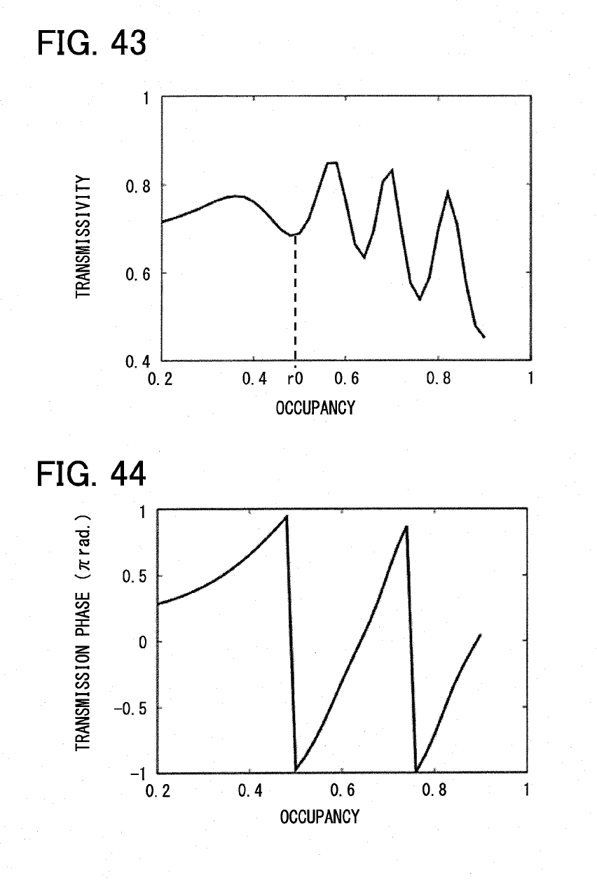

Followingly, the manufacturing process of the lens in the seventh embodiment will be explained with referring to FIG. 42.

Initially, a 501 substrate is prepared. In the SOI substrate, the etching stopper layer 170 made from SiO₂ is formed on the Si substrate 61, and a Si layer 172 made from Si is formed on the etching stopper layer 170.

A mask 173 of a reversed pattern (that is, the same pattern as the space region 63) to the ridge 62 is formed on a surface of the Si layer 172 in the SOI substrate (referring to FIG. 42A). The mask 173 may be any kind of material having resistance to a dry etching, which is the following process.

The Si layer 172 that is not covered with the mask 173 is removed by dry etching, and the Si layer 172 that is covered with the mask 173 is left to provide the ridge 62 (referring to FIG. 42B). In this process, the etching stopper layer 170 functions as the etching stopper, and the etching process is stopped when the etching stopper layer 170 is exposed in every region. Therefore, it is possible that the height of the ridge 62 is uniform. The mask 173 is removed after the dry etching.

Since the occupancy rate r of the unit cell 175 is different according to the region when the etching stopper layer 170 functions as the etching stopper is not provided, the etched depth may change according to the region. That is, the height of the ridge 62 may not be controlled precisely. This is based on a phenomenon called a micro loading effect that an etching rate is different due to a difference in a detail of an etching pattern.

The etching stopper layer 170 exposed in the region between the ridges 62 is removed by a wet etching (referring to FIG. 42C). It may be unnecessary that the etching stopper layer 170 is removed partially. However, since a property, such as a transmissivity or the like, of a lens is affected, it may be preferable to remove the etching stopper layer 170 partially. In the case of the wet etching, a region of the etching stopper layer 170 between the substrate 61 and the ridge 62 may be partially removed. However, when the etching stopper layer 170 is thin, it is possible to reduce the amount of the side etching and to improve a strength of the ridge 62.

As described above, it is possible that the lens of the seventh embodiment is easily manufactured at low cost by using the SOI substrate. In addition, since it is possible that the height of the ridge 62 is uniform, it is possible to reduce a manufacturing error, a performance variation, or the like, and it is possible to manufacture the lens as a designed.

FIG. 43 is a graph illustrating a relationship between the occupancy rate r and the transmissivity when the period length a of the unit cell 175 is equal to 2.8 μm. FIG. 44 is a graph illustrating the transmission phase when the period length a of the unit cell 175 is equal to 2.8 μm. The transmissivity and the transmission phase are calculated as similar to a case in FIG. 33 and FIG. 34.

As described in FIG. 43, the transmissivity in a case where the occupancy rate r is in a range of 0.2 to 0.8 is equal to or more than 50%, and the occupancy rate r is about 70% on average. The transmissivity has three minimal values in the range from 0.2 to 0.8. The minimum occupancy rate r0, which is the smallest occupancy rate r among the occupancy rates r corresponding to the minimal values is about 0.5. As described in FIG. 44, the transmission phase is largely changed around r0. When the occupancy rate r is changed across r0, it may be possible to change the transmission phase largely.

Incidentally, in the sixth embodiment and the seventh embodiment, although the predetermined wavelength λ is set to 10 μm, it is not limited to 10 μm. It may be effective that the predetermined wavelength λ in the sixth embodiment corresponds to mid infrared rays and far infrared rays having a wavelength of 2 μm or more. Especially, the lens in the sixth embodiment and the seventh embodiment may be suitable to a wavelength of 2 μm to 20 μm. More preferably, the predetermined wavelength corresponds to 5 μm to 15 μm.

### Other Modifications

The shape in plan view of the unit cell and a tiling method is not limited to what described in the above embodiments, and any arbitrary shape that fills a plane by a single shape may be used. However, when the lens does not have a polarization property, a regular triangle, a square, or a regular hexagon may be preferred. When the lens has a regular triangle shape or a regular hexagon shape, two patterns of the tiling method for each are considered. Each of the two patterns may be used as the tiling method. When the lens has a polarization property, the shape in plan view of the unit cell may be a rectangle, a parallelogram, a diamond, or the like.

In the first embodiment and the third to seventh embodiments, the shape in plan view of ridge is a square shape. The shape in plan view of the ridge may have a rotational symmetry of the integral multiple of the number of the rotational symmetry of the shape in plan view of the unit cell. For example, the shape in plan view of the ridge may be a regular octagon, a regular dodecagon, a circle, or the like other than a square. It is possible to reduce the polarization property of the lens in the above shape. When the shape in plan view of the unit cell is a triangle shape, the shape in plan view of the ridge is a regular triangle, a regular hexagon, a circle, or the like. When the shape in plan view of the unit cell is a hexagon, the shape of the ridge is a regular dodecagon, a circle, or the like.

In a case where the shape in plan view of the unit cell is a shape other than a square, the shape in plan view of the ridge may be a reduced similar figure of the shape in plan view of the unit cell preferably as described in the first embodiment and the third to seventh embodiments.

Incidentally, the shapes in plan view of the ridge described above may include a shape whose one or several corners are rounded, or may include a shape whose one or several sides are curved. For example, in the ridge having a square shape, one corner of the square is rounded. When a ridge part is processed in a manufacturing of the lens in the present disclosure, a corner of the ridge may be rounded.

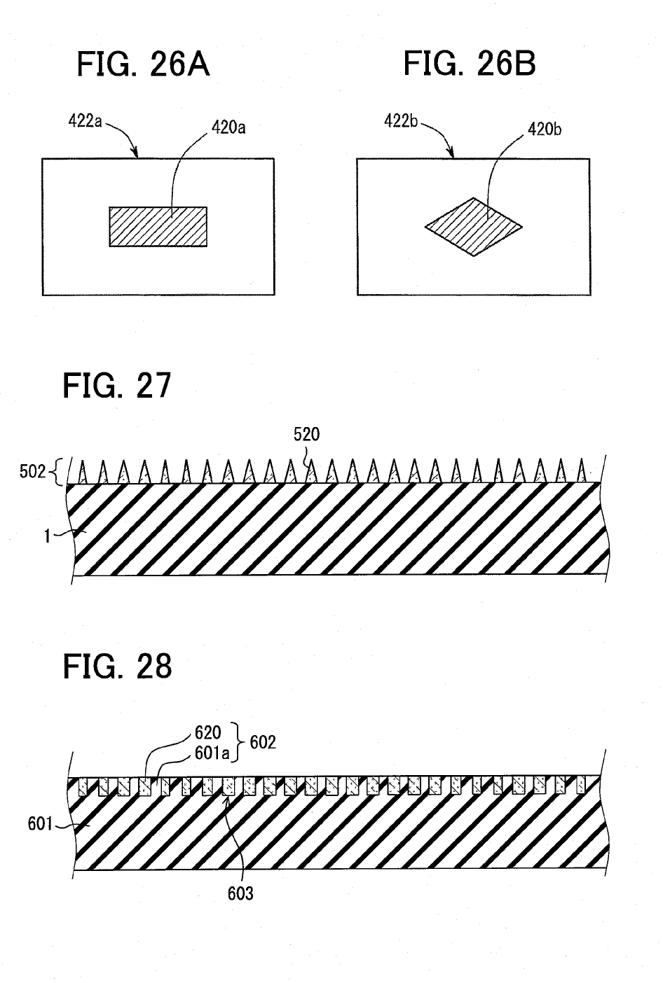

FIG. 24A to FIG. 26B describe modifications of the structure of the unit cell. It should be noted that the modifications are merely examples and that the structure of the unit cell is not limited to the modifications. In FIG. 24A to FIG. 24C, the shape in plan view of unit cells 222a, 222b, 222c is a regular triangle. In FIG. 24A, a shape of the ridge 220a is a regular triangle. In FIG. 24B, a shape of the ridge 220b is a regular hexagon. In FIG. 6C, the shape of a ridge 220c is a circle. In FIG. 25A and FIG. 25B, the shape in plan view of the unit cells 322a, 322b is a regular hexagon. In FIG. 25A, a shape of the ridge is a regular hexagon 320a. In FIG. 25B, the shape of a ridge 320b is a circle. In FIG. 26A and FIG. 26B, the shape in plan view of unit cells 422a, 422b is a rectangle. In FIG. 26A, the shape in plan view of a ridge 420a is a rectangle. In FIG. 26B, a shape of a ridge 420b is a diamond (also referred to as a rhombus shape).

In addition, the shape of the ridge is not limited to a column, a cylinder, or the like. The shape of the ridge may be a circular cone, a pyramid, a circular truncated cone, a truncated pyramid, or the like. As explained in the second modification in the sixth embodiment, when the side surface of the ridge is tilted, it may be possible to improve the transmissivity of the lens.

When a cross sectional area of the ridge along a horizontal direction, which is parallel with a main surface of the substrate 1, changes along a direction, which is perpendicular to the main surface of the substrate 1 (that is, when the shape of ridge corresponds to a circular cone, a pyramid, a circular truncated cone, a truncated pyramid, or the like), the occupancy rate is defined using the cross section area in the horizontal direction at the nearest position to the substrate.

FIG. 27 is a cross sectional view of the lens when the shape of the ridge 520 in the quasi-periodic structure layer 502 is a circular cone or a pyramid. When the cross sectional area of the ridge 520 along the horizontal direction decreases gradually as a distance from the substrate 1, the average refractive index of the quasi-periodic structure layer 502 increases as a position in the ridge 520 approaches to the substrate 1. Therefore, in a case where light is incident from the main surface of the quasi-periodic structure layer 502, a reflection of light at a surface of the quasi-periodic structure payer 502 is reduced, so that it is possible to improve the transmissivity of the lens.

In the first to seventh embodiments, the first region according to the present disclosure corresponds to the ridge, that is, a projection portion. However, the first region according to the present disclosure is not limited to this configuration. The first region may be a recess portion instead of the projection portion, for example. The first region may be multiple projection portions or may be multiple recess portions. The one first region may include multiple projection portions or may be multiple recess portions.

In the first to fifth embodiments, the substrate 1 is made from SiO₂ (fused quartz), the first region in the quasi-periodic structure layer 2 is the ridge 20 made from Si, and the second region in the quasi-periodic structure layer 2 is the space region 21. However, any arbitrary material may be used as long as the following condition is satisfied: n2≧n1>n3 or n2>n1≧n3. For example, the ridge 20 may be made from a semiconductor made from Ge, GaAs, GaN, or the like. A vacuum region may be used instead of the space region 21. Alternatively, the space region 21 may be filled with various dielectric materials such as metal oxide, conductive oxide, resin, alcohol, or the like. The substrate 1 and the ridge 20 may be made from the same material, or the substrate 1 and the space region 21 may be made from the same material.

FIG. 28 is a cross sectional view of a lens in the present disclosure. A recess portion 603 is provided on a surface of the substrate 601 made from SiO₂. The recess portion 603 has the same shape as the ridge 20 in the first embodiment. The recess portion 603 is filled with Si to be a ridge 620. This is a case where the space region 21 and the substrate 1 are made from the same material, which is SiO₂. The quasi-periodic structure layer 602 is formed with a region 601a provided between the ridges 620, and the ridge 20 in the substrate 601.

The lens in the first to fifth embodiments condenses light of 1.55 μm of wavelength. The present disclosure is not limited to this wavelength, and the lens may condense or diverge light having arbitrary wavelength. It may be preferable that the lens in the present disclosure condenses or diverges a visible light to a near-infrared light. It may be easily to manufacture the lens having an excellent property when the predetermined wavelength is set from 0.4 μm to 12 μm, the predetermined wavelength is set between ⅓ to ⅔ of the predetermined wavelength, the lower limit of the variation range of the occupancy rate is equal to 0.2 or more, and the upper limit of the variation range of the occupancy rate is equal to 0.8 or less.

The lens in the first to seventh embodiments is a transmission type lens that condenses light transmitting the lens. However, the lens may be a reflection type lens that condenses a reflected light. Alternatively, the lens may diverge the transmitted light or the reflected light instead of condensing light. The lens may be manufactured by appropriately designing a material of the substrate 1, a material of the quasi-periodic structure layer 2, and a variation of the occupancy rate r.

In the first to seventh embodiments, the quasi-periodic structure layer is formed at the main surface of the substrate. However, the quasi-periodic structure layer may be formed on both of the main surface and the back surface of the substrate.

It should be noted that various conventional technology may be applied to the lens in the first to seventh embodiments. For example, an AR coat or a moth-eye film may be provided to a surface of the lens receiving light, so that a reflection on a lens surface may be reduced. In addition, a layer such as dielectric multilayer film may be inserted between the substrate and the quasi-periodic structure layer. In addition, an optical filter or the like may be provided to the lens surface. In addition, in order to prevent a physical or chemical damage to the quasi-periodic structure layer, in order to improve an environment resistance, and in order to prevent deterioration with time, a cap layer, which is made from SiO₂ or the like, may be provided by covering the quasi-periodic structure layer.

As described above, it is possible that the lens in the present disclosure is used as a cheap and thin convex lens or concave lens.

According to first aspect of the present disclosure, a lens reflecting a light of a predetermined wavelength, or transmitting and condensing or diverging the light is provided. The lens includes a substrate and a quasi-periodic structure layer positioned to the substrate. A plane of the quasi-periodic structure layer is divided into unit cells and is filled with the unit cells in a two-dimensional period. Each of the unit cells in the quasi-periodic structure layer has a first region and a second region. A refractive index of the substrate is expressed by n1. A refractive index of the first region is expressed by n2. A refractive index of the second region is expressed by n3. A following relationship is satisfied: n2≧n1>n3 or n2>n1≧n3. A ratio of an area of the first region to an area of one of the unit cells is defined as an occupancy rate. The occupancy rate of each of the unit cells is changed as each of the unit cells has a distance from a center of the substrate, and a plan-view shape of the first region remains a similar figure. In a virtual arrangement, the plane of the quasi-periodic structure layer is filled with the unit cells that have the occupancy rate and a period length in the two-dimensional period, the occupancy rate and the period length being constant over the plane of the quasi-periodic structure layer. A resonance mode is defined by a relationship between the occupancy rate and the period length in a condition where the occupancy rate and the period length are changed and a transmissivity of the virtual arrangement is equal to 0.1. A lowest order resonance mode is defined as the resonance mode in a case where the occupancy rate is minimal. An optimum value is a smallest value of a resonance width of the lowest order resonance mode. The period length of the unit cells in an actual quasi-periodic structure layer is set to a predetermined value within a predetermined range including the optimum value. A variation range of the occupancy rate of each of the unit cells changes across the lowest order resonance mode.

According to second aspect of the present disclosure, a lens reflecting a light of a predetermined wavelength, or transmitting and condensing or diverging the light is provided. The lens includes a substrate and a quasi-periodic structure layer positioned to the substrate. The predetermined wavelength is equal to or more than 2 μm. A plane of the quasi-periodic structure layer is divided into unit cells and is filled with the unit cells in a two-dimensional period. Each of the unit cells in the quasi-periodic structure layer has a first region, which is the same material as the substrate, and a second region. A refractive index of the substrate is expressed by n1. A refractive index of the first region is expressed by n2. A refractive index of the second region is expressed by n3. A following relationship is satisfied: n1=n2>n3 and n1 is equal to or more than 3. A square root of a ratio of an area of the first region to an area of one of the unit cells is defined as an occupancy rate. The occupancy rate of each of the unit cells is changed as each of the unit cells has a distance from a center of the substrate, and a plan-view shape of the first region remains a similar figure. In a virtual arrangement, the plane of the quasi-periodic structure layer is filled with the unit cells that have the occupancy rate and a period length in the two-dimensional period, the occupancy rate and the period length being constant over the plane of the quasi-periodic structure layer. A minimum occupancy rate is defined to the smallest occupancy rate when the occupancy rate is changed in a predetermined period length and the transmissivity of the virtual arrangement has the smallest value. A variation range of the occupancy rate in the unit cells in an actual quasi-periodic structure changes across the minimum occupancy rate.

The refractive index according to the present disclosure represents a value about a light of a wavelength (corresponding to the predetermined wavelength) transmitting the lens or reflected by the lens, and represents a real number part of a complex refractive index. The refractive indexes of the substrate and the first region in the first aspect of the present disclosure may be identical each other, or the refractive indexes of the substrate and the second region may be identical each other.

A shape in plan view of the unit cell may be any arbitrary shape as long as a plane filling is performed. For example, the shape in plan view of the unit cell may be a regular triangle, a square, a regular hexagon, in which periods in two axes are identical. In a case where a shape has a high rotational symmetry property, it is possible that the lens in the present disclosure condenses or diverges light irrespective of a polarization direction. The shape in plan view of the first region may have a rotational symmetry property of integer multiple of the shape of the unit cell, preferably. Thus, when the unit cell is a regular triangle shape, it may be preferable that the shape of the first region has a rotational symmetry of the integer multiple of three. Similarly, when the unit cell is a square, the first region may have a rotational symmetry of the integer multiple of four preferably. When the unit cell is a regular hexagon, the first region may have a rotational symmetry of the integer multiple of six preferably. Since a circle has infinite rotational symmetry, the shape of the first region may be a circle in any case. Incidentally, when the unit cell is a square, two tiling methods are considered. In one case, the unit cells are filled in a square-lattice like from, and in another case, the unit cells are filled in a form that each lattice are shifted alternately. The both forms may be utilized. Similarly, two forms may be considered when the shape of the unit cell is a regular triangle, and the both forms may be utilized.

It is supposed that the shape in plan view of the unit cell is a square and the unit cells are filled in the square-lattice form. In this case, it should be configured that the following expression is satisfied: a>λ²/(n2×h). Herein, the period length is expressed by a, the predetermined wavelength is expressed by λ, and the thickness of the quasi-periodic structure layer is expressed by h. According to this configuration, a structure of the quasi-periodic structure may not be fine so much, and the lens may be manufactured easily.

Alternatively, the shape in plan view of the unit cell may be a shape in which the periods in two axes are different, such as a rectangle, a parallelogram, or the like. In this case, the lens in the present disclosure may have a polarization dependency in condensing or divergence of light. It is possible to control the polarization dependency according to the period of the two axes in the unit cell. Similarly, in a case where the shape in plan view in the first region is a rectangle, a parallelogram, or the like, it is possible to implement the lens having a polarization dependency.

It may be preferable that the shape of the first region is a reduced similar figure of the unit cell even when the unit cell has any shape in plan view.

Incidentally, the shape in plan view of the first region may not have a rotational symmetry strictly. For example, the shape having the rotational symmetry in the present disclosure includes a regular triangle, a square and a regular hexagon whose several corners are rounded, the above shapes whose side(s) is gently curved, and the above shapes whose corner(s) is rounded and side(s) is gently curved.

In the first aspect of the present disclosure, the substrate, the first region, and the second region may be any kind of material as long as the following expression: n2≧n1>n3 or n2>n1≧n3. The second region may be a space region that is filled with air. The substrate, the first region and the second region may be made from a dielectric, a semiconductor, a conductive oxide, or the like. For example, the substrate may be made from SiO₂, the first region may be made from Si, and the second region may by the space region filled with air. In this case, it is possible that the lens in the present disclosure is manufacture by utilizing a manufacturing process of a Si semiconductor, and therefore, it is possible to reduce a manufacturing cost.

In addition, in the second aspect of the present disclosure, the substrate and the first region may be any kind of material as long as the refractive index of the substrate and the first region are equal to or more than 3 and are more than the refractive index of the second region. The second region may be a space region that is filled with air. The substrate and the first region may be Si, Ge, SiGe, GaAs, GaN, or the like. Especially, it may be preferable that the substrate and the first region is made from Si, and the second region is the space region. In this case, it is possible that the lens in the present disclosure is manufacture by utilizing a manufacturing process of a Si semiconductor, and therefore, it is possible to reduce a manufacturing cost.

With respect to specific structures of the first region and the second region, the first region may be a ridge (that is, a projection portion), which corresponds to an isolated portion or an island portion, and the second region may surround the first region. Alternatively, at the center of the first region, a hole corresponding to the second region may be provided, the hole being an isolated portion or an island portion. It should be noted that the structure of the first region and the second region is not limited these structures. Especially, it may be preferable that the sectional area of the first region parallel to the substrate is reduced as a distance from the substrate. It may be possible to improve a transmissivity of the lens. For example, a shape of the first region may be a truncated pyramid, a truncated cone, a pyramid, a corn, or the like. It may be preferable that a tilt angle of a side surface of the shapes is equal to or less than 5 degree.

The resonance mode is defined as follows. It is supposed to be a virtual arrangement that unit cells with a constant occupancy rate r and a constant period length a are filled in a two-dimensional period on a plane. In this case, a transmissivity T of the virtual arrangement is expressed by a function of r and a and expressed by the following expression: T=f(r,a). The resonance mode is defined by a curve satisfying a condition where the transmissivity T is equal to or less than 0.1 or defined by a belt shaped region satisfying a condition where f (r, a)≦0.1. Usually, there are several resonance modes due to an influence of diffraction. Thus, in the multiple resonance modes, a curve with the smallest occupancy rate is defined as the lowest order resonance mode.

The resonance width of the lowest order resonance mode is defined as a half vale width of a peak where the transmissivity T is reduced. Since the transmissivity T is a function of the occupancy rate r and the period length a, the resonance width may be defined by a half value width of a direction of the occupancy rate r, or may be defined by a half value width of a direction of the period length a.

The predetermined range including a value (the optimum value) in which the resonance width of the lowest order resonance mode becomes narrowest may be determined arbitrarily as long as the lens has a desired property with respect to the transmissivity or a reflection index of the lens and a condensation or divergence of the light. However, it may be preferable that the predetermined range is in a range from 0.9 to 1.1 times of the optimum value. When the predetermined range is in the range from 0.9 to 1.1 times of the optimum value, the transmissivity of the lens may not decrease so much. More preferably, the predetermined range may be in a range from 0.95 to 1.05 times of the optimum value.

When the resonance width is expressed by the occupancy rate, a step width that changes the occupancy rate in the actual quasi-periodic structure layer may be preferably set so that the number of change points of the occupancy rate existing in the resonance width is 0.1 times or less of the number of all change points of the occupancy rate in the quasi-periodic structure layer. In this case, there may be a few unit cells whose transmissivity is equal to zero, and an influence on the transmissivity may be reduced as a whole of the lens. More preferably, the step width may be set so that the number of change points of the occupancy rate is 0.01 times or less of the total number of all change points of the occupancy rate.

In addition, when the resonance width is expressed by the occupancy rate, the step width that changes the occupancy rate in the actual quasi-periodic structure layer may be set larger than the resonance width preferably.

In this case, the number of change points of the occupancy rate existing in the resonance width is one at most, and therefore, the influence on the transmissivity may be more reduced as the whole of the lens.

In addition, it may be preferable that the variation range of the occupancy rate is set so that the resonance width of the lowest order resonance mode is overlapped with a range of 0.8 or more to 1.1 or less of a median of the variation range of the occupancy rate. In this case, it may be possible that a variation width of a transmission phase is enlarged easily. In addition, it may be preferable that the variation range of the occupancy rate is set so that the transmission phase is changed from −π to π.

The occupancy rate of each unit cell may repeatedly increase or decrease in a saw-tooth shape as a distance from the center of the substrate (that is, as a position of the unit cell is separated from the center of the substrate). According to this configuration, it is possible to obtain effects as similar to the Fresnel lens, and it is possible to shorten a focal distance of the lens in the present disclosure.

A peripheral region of the quasi-periodic structure layer may be a periodic structure with a constant occupancy rate. According to this periodic structure, since the light is reflected, it is possible that the peripheral region of the quasi-periodic structure layer functions as an aperture. The aperture functions as a diaphragm to limit a region where the light transmits. Especially, when the periodic structure of the peripheral region is the same as the period length of the unit cell, the lens in the present disclosure may be manufactured more easily.

In addition, the periodic structure layer with a constant occupancy rate may be provided on a surface of the substrate opposite to the quasi-periodic structure layer. Alternatively, between the substrate and the periodic structure, a low refractive layer having a refractive index lower than the substrate may be provided. According to this configuration, it is possible that light of wavelength other than a desired wavelength is prevented from transmitting the periodic structure layer. In addition, instead of the above periodic structure layer, an absorption layer that absorbs light of wavelength other than the desired wavelength may be provided. Accordingly, it is possible that light of wavelength other than a desired wavelength is prevented from transmitting the periodic structure layer.

Alternatively, an imaging element array may be provided on a surface of the substrate opposite to the quasi-periodic structure layer or the surface of the quasi-periodic structure layer, and may be integrated with the lens in the present disclosure. An air layer or a dielectric layer may be provided between the imaging element array and the substrate or between the imaging element array and the quasi-periodic structure layer.

In addition, a low refractive layer having a refractive index lower than the refractive index of the first region may be provided above the first region. It may be possible to improve the transmissivity of the lens.

In addition, an etching stopper layer having resistance to an etching of the first region may be provided between the substrate and the first region. In this case, it may be easy to make uniform a height of the first region when the first region is formed with the etching.

The lens in first aspect of the present disclosure is especially suitable for condensing or diverging a visible light or a near infrared ray. When the predetermined wavelength is set from 0.4 μm or more to 12 μm or less, the predetermined wavelength is set between ⅓ to ⅔ of the predetermined wavelength, the lower limit of the variation range of the occupancy rate is equal to 0.2 or more, and the upper limit of the variation range of the occupancy rate is equal to 0.8 or less, it may be easily to manufacture the lens in the present disclosure, the lens having an excellent property.

It may be preferable that the period length of the lens in the second aspect of the present disclosure is equal to or more than ½ of λ/n1 to equal to or less than 5/4 of λ/n1. The symbol λ means the predetermined wavelength. It may be possible to improve the transmissivity of the lens.

In addition, the lens in the second aspect of the present disclosure is used to condense or diverge a light having the predetermined wavelength of 2 μm or more. It may be preferable that the predetermined wavelength is from 5 μm to 15 μm.

According to another aspect of the present disclosure, a manufacturing method of lens is provided. The manufacturing method includes providing a quasi-periodic structure layer on a substrate, and dividing a plane of the quasi-periodic structure layer into unit cells. In the providing the quasi-periodic structure layer, the a plane of the quasi-periodic structure layer is filled with the unit cells in a two-dimensional period, each of the unit cells in the quasi-periodic structure layer has a first region and a second region, a refractive index of the substrate is expressed by n1, a refractive index of the first region is expressed by n2, a refractive index of the second region is expressed by n3, a following relationship is satisfied: n2≧n1>n3 or n2>n1≧n3, a square root of a ratio of an area of the first region to an area of the unit cell is defined as an occupancy rate of each of the unit cells, the occupancy rate is changed as a distance from a center of the substrate, and a plan-view shape of the first region in each of the unit cells remains similar figures, In a virtual arrangement, the plane of the quasi-periodic structure layer is filled with the unit cells with a constant occupancy rate and a constant period length in the two-dimensional period, a resonance mode is defined by a relationship between the occupancy rate and the period length in a case where the occupancy rate and the period length are changed and the transmissivity of the virtual arrangement is equal to zero, a lowest order resonance mode is defined by the resonance mode in a case where the occupancy rate is minimum, the period length of the unit cells in an actual quasi-periodic structure layer is set to a predetermined value within a predetermined range including an optimum value that the resonance width of the lowest order resonance mode becomes narrowest, and a variation range of the occupancy rate of each of the unit cells changes across the lowest order resonance mode.

According to the present disclosure, it is possible to prolong a period of the unit cell of the quasi-periodic structure layer without reducing the transmissivity, and it is possible to manufacture the thin lens at a low cost.

It should be noted that the configuration described in the present embodiments may be used on its own, and may be used in any combinations. For example, the configuration having the low refractive layer on the ridge as described in the first modification in the sixth embodiment may be added to the structure described in the first to seventh embodiments.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A lens reflecting a light of a predetermined wavelength, or transmitting and condensing or diverging the light, the lens comprising:
a substrate; and
a quasi-periodic structure layer positioned to the substrate, wherein
a plane of the quasi-periodic structure layer is divided into unit cells,
the plane of the quasi-periodic structure layer is filled with the unit cells in a two-dimensional period,
each of the unit cells in the quasi-periodic structure layer has a first region and a second region,
a refractive index of the substrate is expressed by n1,
a refractive index of the first region is expressed by n2,
a refractive index of the second region is expressed by n3,
a following relationship is satisfied:
n2≧n1>n3, or n2>n1≧n3,
an occupancy rate is defined by a square root of a ratio of an area of the first region to an area of one of the unit cells,
the occupancy rate of each of the unit cells is changed as each of the unit cells has a distance from a center of the substrate, and a plan-view shape of the first region remains a similar figure,
in a virtual arrangement, the plane of the quasi-periodic structure layer is filled with the unit cells that have the occupancy rate and a period length in the two-dimensional period, the occupancy rate and the period length being constant over the plane of the quasi-periodic structure layer,
a resonance mode is defined by a relationship between the occupancy rate and the period length in a condition where the occupancy rate and the period length are changed and a transmissivity of the virtual arrangement is equal to or less than 0.1,
a lowest order resonance mode is defined as the resonance mode in a case where the occupancy rate is minimal,
an optimum value is a smallest value of a resonance width of the lowest order resonance mode,
the period length of the unit cells in an actual quasi-periodic structure layer is set to a predetermined value within a predetermined range including the optimum value, and
a variation range of the occupancy rate of each of the unit cells changes across the lowest order resonance mode.

2. The lens according to claim 1, wherein
the predetermined range of the period length is 0.9 times or more to 1.1 times or less of the optimum value.

3. The lens according to claim 1, wherein
the resonance width is expressed by the occupancy rate,
a step width changing the occupancy rate in the actual quasi-periodic structure layer satisfies a condition that a total number of change points of the occupancy rate in the resonance width is equal to or less than 0.1 times of a total number of all change points of the occupancy rate in the actual quasi-periodic structure layer.

4. The lens according to claim 1, wherein
the resonance width is expressed by the occupancy rate,
a step width changing the occupancy rate in the actual quasi-periodic structure layer is larger than the resonance width.

5. The lens according to claim 1, wherein
the variation range of the occupancy rate satisfies a condition that the resonance width of the lowest order resonance mode overlaps with a range of 0.8 to 1.1 of a median of the variation range of the occupancy rate.

6. The lens according to claim 1, wherein
the substrate is made from SiO₂,
the first region is made from Si, and
the second region is a space region filled with air.

7. The lens according to claim 1, wherein
the predetermined wavelength corresponds to a wavelength of a visible light or a near infrared ray.

8. The lens according to claim 1, wherein
the predetermined wavelength is 0.4 μm or more and 12 μm or less,
the period length corresponds to ⅓ to ⅔ of the predetermined wavelength, and
a lower limit of the variation range of the occupancy rate is 0.2 or more and 0.8 or less.

9. A lens reflecting a light of a predetermined wavelength, or transmitting and condensing or diverging the light, the lens comprising:
a substrate; and
a quasi-periodic structure layer positioned to the substrate, wherein
the predetermined wavelength is equal to or more than 2 μm,
a plane of the quasi-periodic structure layer is divided into unit cells,
the plane of the quasi-periodic structure layer is filled with the unit cells in a two-dimensional period,
each of the unit cells in the quasi-periodic structure layer has a first region and a second region,
the first region is made from a same material as the substrate,
a refractive index of the substrate is expressed by n1,
a refractive index of the first region is expressed by n2,
a refractive index of the second region is expressed by n3,
a following relationship is satisfied:
n1=n2>n3, and n1≧3,
an occupancy rate is defined by a square root of a ratio of an area of the first region to an area of one of the unit cells,
the occupancy rate of each of the unit cells is changed as each of the unit cells has a distance from a center of the substrate, and a plan-view shape of the first region remains a similar figure,
in a virtual arrangement, the plane of the quasi-periodic structure layer is filled with the unit cells that have the occupancy rate and a period length in the two-dimensional period, the occupancy rate and the period length being constant over the plane of the quasi-periodic structure layer,
a minimum occupancy rate is defined by a smallest occupancy rate when the occupancy rate is changed in a predetermined period length and a transmissivity in a virtual arrangement has a smallest value, and
a variation range of the occupancy rate of each unit cell in an actual quasi-periodic structure layer changes across the minimum occupancy rate.

10. The lens according to claim 9, wherein
the substrate is made from Si,
the first region is made from Si, and
the second region is a space region filled with air.

11. The lens according to claim 10, wherein
the predetermined wavelength corresponds to 5 μm or more and 15 μm or less.

12. The lens according to claim 9, wherein
the predetermined wavelength is expressed by λ, and
the period length corresponds to ½ times of λ/n1 or more and 5/4 times of λ/n1 or less.

13. The lens according to claim 1, wherein
the occupancy rate of each of the unit cells in the quasi-periodic structure layer repeatedly increase or decrease in a saw-tooth shape as a distance from the center of the substrate.

14. The lens according to claim 1, wherein
a plan-view shape of the unit cells is a regular triangle, a square, or a regular hexagon, and
the plan-view shape of the first region has a rotational symmetry of integer times of the plan-view shape of the unit cells.

15. The lens according to claim 1, wherein
a plan-view shape of the unit cells is square,
the lens is filled with the unit cells in a square lattice form,
the period length of the unit cells is expressed by a,
the predetermined wavelength is expressed by λ,
a thickness of the quasi-periodic structure layer is expressed by h, and
a following expression is satisfied:
a>λ²/(n2×h).

16. The lens according to claim 1, wherein
the plan-view shape of the first region is a rectangle or a parallelogram.

17. The lens according to claim 1, wherein
the plan-view shape of the first region has a reduced similar figure of each of the unit cells.

18. The lens according to claim 1 further comprising
a peripheral region of the quasi-periodic structure layer, the peripheral region having a periodic structure, wherein
the occupancy rate of the peripheral region is constant.

19. The lens according to claim 1 further comprising
another periodic structure positioned at a surface of the substrate opposite to the quasi-periodic structure layer.

20. The lens according to claim 19 further comprising
a refraction layer whose refractive index is lower than a refractive index of the substrate.

21. The lens according to claim 1 further comprising
an absorption layer positioned at a surface of the substrate opposite to the quasi-periodic structure layer.

22. The lens according to claim 1 further comprising
an imaging element array positioned above a surface of the substrate opposite to the quasi-periodic structure layer or
the imaging element array positioned above the quasi-periodic structure layer.

23. The lens according to claim 1 further comprising
an etching stopper layer provided between the substrate and the first region, wherein
the etching stopper layer has resistance to etching of the first region.

24. The lens according to claim 1, wherein
a cross sectional area parallel to the substrate in the first region reduces as a distance from the substrate.

25. The lens according to claim 1, wherein
the first region is a truncated pyramid, a circular truncated cone, a pyramid, or a circular cone.

26. The lens according to claim 25, wherein
a tilt angle of a side surface of the first region is equal to or less than 5 degrees.

27. The lens according to claim 1 further comprising
a low refractive layer is provided on the first region, wherein
the low refractive layer has a refractive index lower than a refractive index of the first region.

28. A manufacturing method of a lens comprising:
providing a quasi-periodic structure layer on a substrate, wherein
in the providing the quasi-periodic structure layer,
a plane of the quasi-periodic structure layer is divided into unit cells and is filled with the unit cells in a two-dimensional period,
each of the unit cells in the quasi-periodic structure layer has a first region and a second region,
a refractive index of the substrate is expressed by n1,
a refractive index of the first region is expressed by n2,
a refractive index of the second region is expressed by n3,
a following relationship is satisfied:
n2≧n1>n3, or n2>n1≧n3,
an occupancy rate is defined by a square root of a ratio of an area of the first region to an area of one of the unit cells,
the occupancy rate of each of the unit cells is changed as each of the unit cells has a distance from a center of the substrate, and a plan-view shape of the first region remains a similar figure,
in a virtual arrangement, the plane of the quasi-periodic structure layer is filled with the unit cells, which have the occupancy rate and a period length, in the two-dimensional period, the occupancy rate and the period length being constant over the plane of the quasi-periodic structure layer,
a resonance mode is defined by a relationship between the occupancy rate and the period length in a condition where the occupancy rate and the period length are changed and a transmissivity of the virtual arrangement is equal to zero,
a lowest order resonance mode is defined as the resonance mode in a case where the occupancy rate is minimal,
an optimum value is a smallest value of a resonance width of the lowest order resonance mode,
the period length of the unit cells in an actual quasi-periodic structure layer is set to a predetermined value within a predetermined range including the optimum value, and
a variation range of the occupancy rate of each of the unit cells changes across the lowest order resonance mode.

29. A manufacturing method of a lens reflecting a light of a wavelength of 2 μm or more, or transmitting and condensing or diverging the light, the manufacturing method comprising:
providing a quasi-periodic structure layer on a substrate, wherein
in the providing the quasi-periodic structure layer,
a plane of the quasi-periodic structure layer is divided into unit cells,
the plane of the quasi-periodic structure layer is filled with the unit cells in a two-dimensional period,
each of the unit cells in the quasi-periodic structure layer has a first region and a second region,
the first region is made from a same material as the substrate,
a refractive index of the substrate is expressed by n1,
a refractive index of the first region is expressed by n2,
a refractive index of the second region is expressed by n3,
a following relationship is satisfied:
n1=n2>n3, and n1≧3,
an occupancy rate is defined by a square root of a ratio of an area of the first region to an area of one of the unit cells,
the occupancy rate of each of the unit cells is changed as each of the unit cells has a distance from a center of the substrate, and a plan-view shape of the first region remains a similar figure,
in a virtual arrangement, the plane of the quasi-periodic structure layer is filled with the unit cells that have the occupancy rate and a period length in the two-dimensional period, the occupancy rate and the period length being constant over the plane of the quasi-periodic structure layer,
a minimum occupancy rate is defined by a smallest occupancy rate when the occupancy rate is changed in a predetermined period length and a transmissivity of a virtual arrangement has a smallest value, and
a variation range of the occupancy rate of each unit cell in an actual quasi-periodic structure layer changes across the minimum occupancy rate.

30. The lens according to claim 9, wherein
the occupancy rate of each of the unit cells in the quasi-periodic structure layer repeatedly increase or decrease in a saw-tooth shape as a distance from the center of the substrate.

31. The lens according to claim 9, wherein
a plan-view shape of the unit cells is a regular triangle, a square, or a regular hexagon, and
the plan-view shape of the first region has a rotational symmetry of integer times of the plan-view shape of the unit cells.

32. The lens according to claim 9, wherein
a plan-view shape of the unit cells is square,
the lens is filled with the unit cells in a square lattice form,
the period length of the unit cells is expressed by a,
the predetermined wavelength is expressed by λ,
a thickness of the quasi-periodic structure layer is expressed by h, and
a following expression is satisfied:
a>λ²/(n2×h).

33. The lens according to claim 9, wherein
the plan-view shape of the first region is a rectangle or a parallelogram.

34. The lens according to claim 9, wherein
the plan-view shape of the first region has a reduced similar figure of each of the unit cells.

35. The lens according to claim 9 further comprising
a peripheral region of the quasi-periodic structure layer, the peripheral region having a periodic structure, wherein
the occupancy rate of the peripheral region is constant.

36. The lens according to claim 9 further comprising
another periodic structure positioned at a surface of the substrate opposite to the quasi-periodic structure layer.

37. The lens according to claim 36 further comprising
a refraction layer whose refractive index is lower than a refractive index of the substrate.

38. The lens according to claim 9 further comprising
an absorption layer positioned at a surface of the substrate opposite to the quasi-periodic structure layer.

39. The lens according to claim 9 further comprising
an imaging element array positioned above a surface of the substrate opposite to the quasi-periodic structure layer, or
the imaging element array positioned above the quasi-periodic structure layer.

40. The lens according to claim 9 further comprising
an etching stopper layer provided between the substrate and the first region and having resistance to etching of the first region.

41. The lens according to claim 9, wherein
a cross sectional area parallel to the substrate in the first region reduces as a distance from the substrate.

42. The lens according to claim 41, wherein
the first region is a truncated pyramid, a circular truncated cone, a pyramid, or a circular cone.

43. The lens according to claim 42, wherein
a tilt angle of a side surface of the first region is equal to or less than 5 degrees.

44. The lens according to claim 9 further comprising
a low refractive layer is provided on the first region, wherein
the low refractive layer has a refractive index lower than a refractive index of the first region.
